(19) United States
(12) Patent Application Publication
(10) Pub. No.: US 2024/0411954 A1
(43) Pub. Date: Dec. 12, 2024

(54) RESERVOIR SIMULATOR

(71) Applicant: Schlumberger Technology Corporation, Sugar Land, TX (US)

(72) Inventors: Surej Kumar Subbiah, Doha (QA); Assef Mohamad Hussein, Crawley (GB); Ying Ru Chen, Doha (QA); Andrew Pearce, Abingdon (GB); Adrian Enrique Rodriguez Herrera, Crawley (GB); Qinglai Ni

(21) Appl. No.: 18/698,171

(22) PCT Filed: Oct. 17, 2022
(86) PCT No.: PCT/US2022/046825

§ 371 Date: Apr. 3, 2024

Related U.S. Application Data
(60) Provisional application No. 63/256,596, filed on Oct. 17, 2021.

(51) Int. Cl. G06F 30/20; E21B 43/00; G01V 20/00

(52) U.S. Cl. CPC G06F 30/20; E21B 43/00; G01V 20/00; E21B 2200/20; G01V 2210/6242; G01V 2210/66

(57) ABSTRACT

A method can include constructing a numerical model of a material matrix, where the numerical model includes cells; performing a simulation of physical phenomena with respect to time using the numerical model; during the performing, analyzing one of the cells as to physical characteristics of the material matrix; and, responsive to the analyzing and during the performing, assigning one or more properties to the cell that indicate failure of the material matrix of the cell without removing the cell from the numerical model.

### CROSS-REFERENCE TO RELATED APPLICATION(S)

The subject disclosure claims priority from U.S. Provisional Appl. No. 63/256,596, filed on Oct. 17, 2021, herein incorporated by reference in its entirety.

### BACKGROUND

A reservoir can be a subsurface formation that can be characterized at least in part by its porosity and fluid permeability. As an example, a reservoir may be part of a basin such as a sedimentary basin. A basin can be a depression (e.g., caused by plate tectonic activity, subsidence, etc.) in which sediments accumulate. As an example, where hydrocarbon source rocks occur in combination with appropriate depth and duration of burial, a petroleum system may develop within a basin, which may form a reservoir that includes hydrocarbon fluids (e.g., oil, gas, etc.). Various operations may be performed in the field to access such hydrocarbon fluids and/or produce such hydrocarbon fluids. For example, consider equipment operations where equipment may be controlled to perform one or more operations.

### SUMMARY

A method can include constructing a numerical model of a material matrix, where the numerical model includes cells; performing a simulation of physical phenomena with respect to time using the numerical model; during the performing, analyzing one of the cells as to physical characteristics of the material matrix; and, responsive to the analyzing and during the performing, assigning one or more properties to the cell that indicate failure of the material matrix of the cell without removing the cell from the numerical model. A system can include a processor; memory accessible to the processor; and processor-executable instructions stored in the memory to instruct the system to: construct a numerical model of a material matrix, where the numerical model includes cells; perform a simulation of physical phenomena with respect to time using the numerical model; during the performance, analyze one of the cells as to physical characteristics of the material matrix; and responsive to the analysis and during the performance, assign one or more properties to the cell that indicate failure of the material matrix of the cell without removing the cell from the numerical model and/or without re-gridding the numerical model. One or more computer-readable storage media can include processor-executable instructions to instruct a computing system to: construct a numerical model of a material matrix, where the numerical model includes cells; perform a simulation of physical phenomena with respect to time using the numerical model; during the performance, analyze one of the cells as to physical characteristics of the material matrix; and responsive to the analysis and during the performance, assign one or more properties to the cell that indicate failure of the material matrix of the cell without removing the cell from the numerical model and/or without re-gridding the numerical model. Various other apparatuses, systems, methods, etc., are also disclosed.

This summary is provided to introduce a selection of concepts that are further described below in the detailed description. This summary is not intended to identify key or essential features of the claimed subject matter, nor is it intended to be used as an aid in limiting the scope of the claimed subject matter.

### BRIEF DESCRIPTION OF THE DRAWINGS

Features and advantages of the described implementations can be more readily understood by reference to the following description taken in conjunction with the accompanying drawings.

FIG. 1 illustrates an example system that includes various framework components associated with one or more geologic environments;

FIG. 2 illustrates examples of a basin, a convention and a system;

FIG. 3 illustrates an example of a system;

FIG. 4 illustrates an example of a geologic environment and examples of equipment;

FIG. 5 illustrates examples of equipment and examples of simulators;

FIG. 6 illustrates an example of a method;

FIG. 7 illustrates an example of a method;

FIG. 8 illustrates examples of grids, surfaces and properties;

FIG. 9 illustrates an example of a process;

FIG. 10 illustrates an example of a method;

FIG. 11 illustrates an example of a model;

FIG. 12 illustrates an example of a plot;

FIG. 13 illustrates an example of a plot;

FIG. 14 illustrates example plots;

FIG. 15 illustrates an example of a plot;

FIG. 16 illustrates an example of a process;

FIG. 17 illustrates example of model structures;

FIG. 18 illustrates example of model phenomena;

FIG. 19 illustrates an example of a plot;

FIG. 20 illustrates an example of a method and an example of a system;

FIG. 21 illustrates examples of computer and network equipment; and

FIG. 22 illustrates example components of a system and a networked system.

### DETAILED DESCRIPTION

This description is not to be taken in a limiting sense, but rather is made merely for the purpose of describing the general principles of the implementations. The scope of the described implementations should be ascertained with reference to the issued claims.

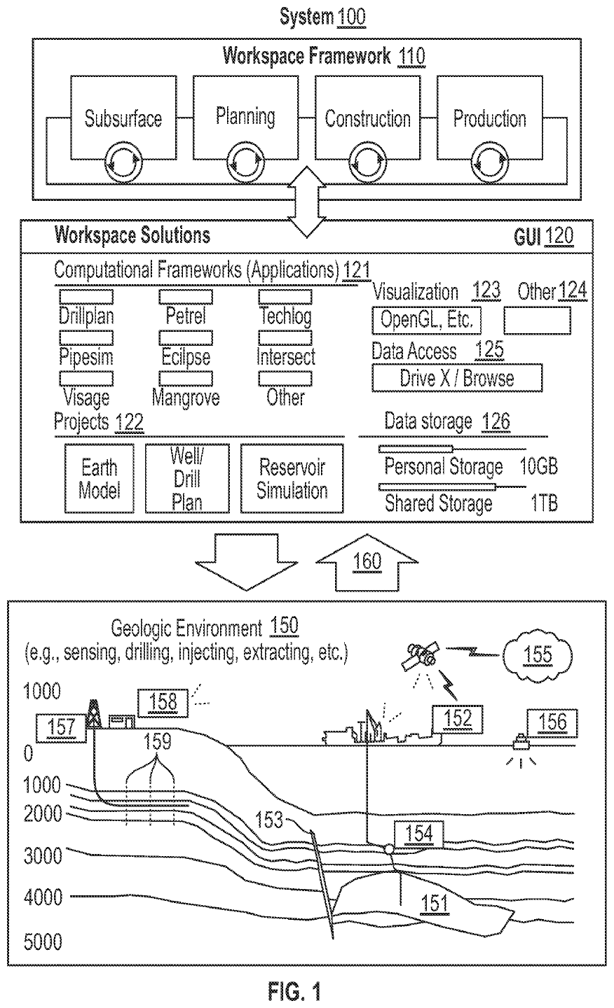

FIG. 1 shows an example of a system 100 that includes a workspace framework 110 that can provide for instantiation of, rendering of, interactions with, etc., a graphical user interface (GUI) 120. In the example of FIG. 1, the GUI 120 can include graphical controls for computational frameworks (e.g., applications) 121, projects 122, visualization 123, one or more other features 124, data access 125, and data storage 126.

In the example of FIG. 1, the workspace framework 110 may be tailored to a particular geologic environment such as an example geologic environment 150. For example, the geologic environment 150 may include layers (e.g., stratification) that include a reservoir 151 and that may be intersected by a fault 153. As an example, the geologic environment 150 may be outfitted with a variety of sensors, detectors, actuators, etc. For example, equipment 152 may include communication circuitry to receive and to transmit information with respect to one or more networks 155. Such information may include information associated with downhole equipment 154, which may be equipment to acquire information, to assist with resource recovery, etc. Other equipment 156 may be located remote from a wellsite and include sensing, detecting, emitting or other circuitry. Such equipment may include storage and communication circuitry to store and to communicate data, instructions, etc. As an example, one or more satellites may be provided for purposes of communications, data acquisition, etc. For example, FIG. 1 shows a satellite in communication with the network 155 that may be configured for communications, noting that the satellite may additionally or alternatively include circuitry for imagery (e.g., spatial, spectral, temporal, radiometric, etc.).

FIG. 1 also shows the geologic environment 150 as optionally including equipment 157 and 158 associated with a well that includes a substantially horizontal portion that may intersect with one or more fractures 159. For example, consider a well in a shale formation that may include natural fractures, artificial fractures (e.g., hydraulic fractures) or a combination of natural and artificial fractures. As an example, a well may be drilled for a reservoir that is laterally extensive. In such an example, lateral variations in properties, stresses, etc. may exist where an assessment of such variations may assist with planning, operations, etc. to develop a laterally extensive reservoir (e.g., via fracturing, injecting, extracting, etc.). As an example, the equipment 157 and/or 158 may include components, a system, systems, etc. for fracturing, seismic sensing, analysis of seismic data, assessment of one or more fractures, etc.

In the example of FIG. 1, the GUI 120 shows some examples of computational frameworks, including the DRILLPLAN, PETREL, TECHLOG, PIPESIM, ECLIPSE, INTERSECT, VISAGE and MANGROVE frameworks (Schlumberger Limited, Houston, Texas).

The DRILLPLAN framework provides for digital well construction planning and includes features for automation of repetitive tasks and validation workflows, enabling improved quality drilling programs (e.g., digital drilling plans, etc.) to be produced quickly with assured coherency.

The PETREL framework can be part of the DELFI cognitive E&P environment (Schlumberger Limited, Houston, Texas) for utilization in geosciences and geoengineering, for example, to analyze subsurface data from exploration to production of fluid from a reservoir.

The TECHLOG framework can handle and process field and laboratory data for a variety of geologic environments (e.g., deepwater exploration, shale, etc.). The TECHLOG framework can structure wellbore data for analyses, planning, etc.

The PIPESIM simulator includes solvers that may provide simulation results such as, for example, multiphase flow results (e.g., from a reservoir to a wellhead and beyond, etc.), flowline and surface facility performance, etc. The PIPESIM simulator may be integrated, for example, with the AVOCET production operations framework (Schlumberger Limited, Houston Texas). As an example, a reservoir or reservoirs may be simulated with respect to one or more enhanced recovery techniques (e.g., consider a thermal process such as steam-assisted gravity drainage (SAGD), etc.). As an example, the PIPESIM simulator may be an optimizer that can optimize one or more operational scenarios at least in part via simulation of physical phenomena.

The ECLIPSE framework provides a reservoir simulator (e.g., as a computational framework) with numerical solutions for fast and accurate prediction of dynamic behavior for various types of reservoirs and development schemes.

The INTERSECT framework provides a high-resolution reservoir simulator for simulation of detailed geological features and quantification of uncertainties, for example, by creating accurate production scenarios and, with the integration of precise models of the surface facilities and field operations, the INTERSECT framework can produce reliable results, which may be continuously updated by real-time data exchanges (e.g., from one or more types of data acquisition equipment in the field that can acquire data during one or more types of field operations, etc.). The INTERSECT framework can provide completion configurations for complex wells where such configurations can be built in the field, can provide detailed chemical-enhanced-oil-recovery (EOR) formulations where such formulations can be implemented in the field, can analyze application of steam injection and other thermal FOR techniques for implementation in the field, advanced production controls in terms of reservoir coupling and flexible field management, and flexibility to script customized solutions for improved modeling and field management control. The INTERSECT framework, as with the other example frameworks, may be utilized as part of the DELFI cognitive E&P environment, for example, for rapid simulation of multiple concurrent cases. For example, a workflow may utilize one or more of the DELFI on demand reservoir simulation features.

The VISAGE framework includes a finite-element geomechanics simulator that can be utilized in one or more workflows. The VISAGE framework includes capabilities for compaction and subsidence, well and completion integrity, cap-rock and fault-seal integrity, fracture behavior, thermal recovery, CO2 disposal, etc. The VISAGE framework may be utilized with the PETRL framework, for example, as to reservoir geomechanics (e.g., simulator configuration, results visualization, etc.). The VISAGE framework may integrate a geomechanics model with one or more of geophysics, geology, petrophysics, and reservoir data.

The VISAGE framework simulator can also be operatively coupled with the ECLIPSE framework reservoir simulator and/or the INTERSECT framework reservoir simulator. As an example, a reservoir simulator can model flow of fluids in a reservoir and calculate pressure, temperature, and saturation (e.g., dynamically, etc.). The VISAGE framework simulator can perform 3D static or 4D flow, pressure, and temperature coupled calculations for rock stresses, deformations, failure, etc. As an example, a two-way coupling between simulators may allow for permeability updating of a reservoir model at one or more selected time steps, updating of mechanical properties in the geomechanics model to account for effects such as changing saturations and water softening, etc.

For relatively large models with millions of cells or those coupled to a reservoir simulation, a framework may provide for parallel geomechanics simulation runs, for example, via local and/or remote clusters.

The VISAGE framework simulator can model hundreds of faults, hundreds of thousands of discrete fractures, and highly heterogeneous models. As an example, degree of complexity that exists in a geological model can be maintained throughout geomechanics analyses.

The VISAGE framework simulator can provide 3D and 4D geomechanics simulation across one or more portions of a field life cycle. Such an approach can allow geoscientists and engineers to assess and mitigate potential geomechanics problems affecting well and completions, stimulation, production, injection, field management, etc.

The MANGROVE framework simulator provides for optimization of stimulation design (e.g., stimulation treatment operations such as hydraulic fracturing) in a reservoir-centric environment. The MANGROVE framework can combine scientific and experimental work to predict geomechanical propagation of hydraulic fractures, reactivation of natural fractures, etc., along with production forecasts within 3D reservoir models (e.g., production from a drainage area of a reservoir where fluid moves via one or more types of fractures to a well and/or from a well). The MANGROVE framework can provide results pertaining to heterogeneous interactions between hydraulic and natural fracture networks, which may assist with optimization of the number and location of fracture treatment stages (e.g., stimulation treatment(s)), for example, to increased perforation efficiency and recovery.

The aforementioned DELFI environment provides various features for workflows as to subsurface analysis, planning, construction and production, for example, as illustrated in the workspace framework 110. As shown in FIG. 1, outputs from the workspace framework 110 can be utilized for directing, controlling, etc., one or more processes in the geologic environment 150 and, feedback 160, can be received via one or more interfaces in one or more forms (e.g., acquired data as to operational conditions, equipment conditions, environment conditions, etc.).

As an example, a workflow may progress to a geology and geophysics (“G&G”) service provider, which may generate a well trajectory, which may involve execution of one or more G&G software packages. Examples of such software packages include the PETREL framework. As an example, a system or systems may utilize a framework such as the DELFI framework (Schlumberger Limited, Houston, Texas). Such a framework may operatively couple various other frameworks to provide for a multi-framework workspace. As an example, the GUI 120 of FIG. 1 may be a GUI of the DELFI framework.

In the example of FIG. 1, the visualization features 123 may be implemented via the workspace framework 110, for example, to perform tasks as associated with one or more of subsurface regions, planning operations, constructing wells and/or surface fluid networks, and producing from a reservoir.

As an example, a visualization process can implement one or more of various features that can be suitable for one or more web applications. For example, a template may involve use of the JAVASCRIPT object notation format (JSON) and/or one or more other languages/formats. As an example, a framework may include one or more converters. For example, consider a JSON to PYTHON converter and/or a PYTHON to JSON converter.

As an example, visualization features can provide for visualization of various earth models, properties, etc., in one or more dimensions. As an example, visualization features can provide for rendering of information in multiple dimensions, which may optionally include multiple resolution rendering. In such an example, information being rendered may be associated with one or more frameworks and/or one or more data stores. As an example, visualization features may include one or more control features for control of equipment, which can include, for example, field equipment that can perform one or more field operations. As an example, a workflow may utilize one or more frameworks to generate information that can be utilized to control one or more types of field equipment (e.g., drilling equipment, wireline equipment, fracturing equipment, etc.).

As to a reservoir model that may be suitable for utilization by a simulator, consider acquisition of seismic data as acquired via reflection seismology, which finds use in geophysics, for example, to estimate properties of subsurface formations. As an example, reflection seismology may provide seismic data representing waves of elastic energy (e.g., as transmitted by P-waves and S-waves, in a frequency range of approximately 1 Hz to approximately 100 Hz). Seismic data may be processed and interpreted, for example, to understand better composition, fluid content, extent and geometry of subsurface rocks. Such interpretation results can be utilized to plan, simulate, perform, etc., one or more operations for production of fluid from a reservoir (e.g., reservoir rock, etc.).

Field acquisition equipment may be utilized to acquire seismic data, which may be in the form of traces where a trace can include values organized with respect to time and/or depth (e.g., consider 1 D, 2D, 3D or 4D seismic data). For example, consider acquisition equipment that acquires digital samples at a rate of one sample per approximately 4 ms. Given a speed of sound in a medium or media, a sample rate may be converted to an approximate distance. For example, the speed of sound in rock may be on the order of around 5 km per second. Thus, a sample time spacing of approximately 4 ms would correspond to a sample “depth” spacing of about 10 meters (e.g., assuming a path length from source to boundary and boundary to sensor). As an example, a trace may be about 4 seconds in duration; thus, for a sampling rate of one sample at about 4 ms intervals, such a trace would include about 1000 samples where latter acquired samples correspond to deeper reflection boundaries. If the 4 second trace duration of the foregoing example is divided by two (e.g., to account for reflection), for a vertically aligned source and sensor, a deepest boundary depth may be estimated to be about 10 km (e.g., assuming a speed of sound of about 5 km per second).

As an example, a model may be a simulated version of a geologic environment. As an example, a simulator may include features for simulating physical phenomena in a geologic environment based at least in part on a model or models. A simulator, such as a reservoir simulator, can simulate fluid flow in a geologic environment based at least in part on a model that can be generated via a framework that receives seismic data. A simulator can be a computerized system (e.g., a computing system) that can execute instructions using one or more processors to solve a system of equations that describe physical phenomena subject to various constraints. In such an example, the system of equations may be spatially defined (e.g., numerically discretized) according to a spatial model that that includes layers of rock, geobodies, etc., that have corresponding positions that can be based on interpretation of seismic and/or other data. A spatial model may be a cell-based model where cells are defined by a grid (e.g., a mesh). A cell in a cell-based model can represent a physical area or volume in a geologic environment where the cell can be assigned physical properties (e.g., permeability, fluid properties, etc.) that may be germane to one or more physical phenomena (e.g., fluid volume, fluid flow, pressure, etc.). A reservoir simulation model can be a spatial model that may be cell-based.

A simulator can be utilized to simulate the exploitation of a real reservoir, for example, to examine different productions scenarios to find an optimal one before production or further production occurs. A reservoir simulator does not provide an exact replica of flow in and production from a reservoir at least in part because the description of the reservoir and the boundary conditions for the equations for flow in a porous rock are generally known with an amount of uncertainty. Certain types of physical phenomena occur at a spatial scale that can be relatively small compared to size of a field. A balance can be struck between model scale and computational resources that results in model cell sizes being of the order of meters; rather than a lesser size (e.g., a level of detail of pores). A modeling and simulation workflow for multiphase flow in porous media (e.g., reservoir rock, etc.) can include generalizing real micro-scale data from macro scale observations (e.g., seismic data and well data) and upscaling to a manageable scale and problem size. Uncertainties can exist in input data and solution procedure such that simulation results too are to some extent uncertain. A process known as history matching can involve comparing simulation results to actual field data acquired during production of fluid from a field. Information gleaned from history matching, can provide for adjustments to a model, data, etc., which can help to increase accuracy of simulation.

As an example, a simulator may utilize various types of constructs, which may be referred to as entities. Entities may include earth entities or geological objects such as wells, surfaces, reservoirs, etc. Entities can include virtual representations of actual physical entities that may be reconstructed for purposes of simulation. Entities may include entities based on data acquired via sensing, observation, etc. (e.g., consider entities based at least in part on seismic data and/or other information). As an example, an entity may be characterized by one or more properties (e.g., a geometrical pillar grid entity of an earth model may be characterized by a porosity property, etc.). Such properties may represent one or more measurements (e.g., acquired data), calculations, etc.

As an example, a simulator may utilize an object-based software framework, which may include entities based on pre-defined classes to facilitate modeling and simulation. As an example, an object class can encapsulate reusable code and associated data structures. Object classes can be used to instantiate object instances for use by a program, script, etc. For example, borehole classes may define objects for representing boreholes based on well data. A model of a basin, a reservoir, etc. may include one or more boreholes where a borehole may be, for example, for measurements, injection, production, etc. As an example, a borehole may be a wellbore of a well, which may be a completed well (e.g., for production of a resource from a reservoir, for injection of material, etc.).

While several simulators are illustrated in the example of FIG. 1, one or more other simulators may be utilized, additionally or alternatively. For example, consider the PETROMOD simulator, etc. The PETROMOD framework provides petroleum systems modeling capabilities that can combine one or more of seismic, well, and geological information to model the evolution of a sedimentary basin. The PETROMOD framework can predict if, and how, a reservoir has been charged with hydrocarbons, including the source and timing of hydrocarbon generation, migration routes, quantities, and hydrocarbon type in the subsurface or at surface conditions.

The PETREL framework provides components that allow for optimization of exploration and development operations. The PETREL framework includes seismic to simulation software components that can output information for use in increasing reservoir performance, for example, by improving asset team productivity. Through use of such a framework, various professionals (e.g., geophysicists, geologists, and reservoir engineers) can develop collaborative workflows and integrate operations to streamline processes (e.g., with respect to one or more geologic environments, etc.). Such a framework may be considered an application (e.g., executable using one or more devices) and may be considered a data-driven application (e.g., where data is input for purposes of modeling, simulating, etc.).

As mentioned, a framework may be implemented within or in a manner operatively coupled to the DELFI cognitive exploration and production (E&P) environment (Schlumberger, Houston, Texas), which is a secure, cognitive, cloud-based collaborative environment that integrates data and workflows with digital technologies, such as artificial intelligence and machine learning. As an example, such an environment can provide for operations that involve one or more frameworks. The DELFI environment may be referred to as the DELFI framework, which may be a framework of frameworks. As an example, the DELFI framework can include various other frameworks, which can include, for example, one or more types of models (e.g., simulation models, etc.).

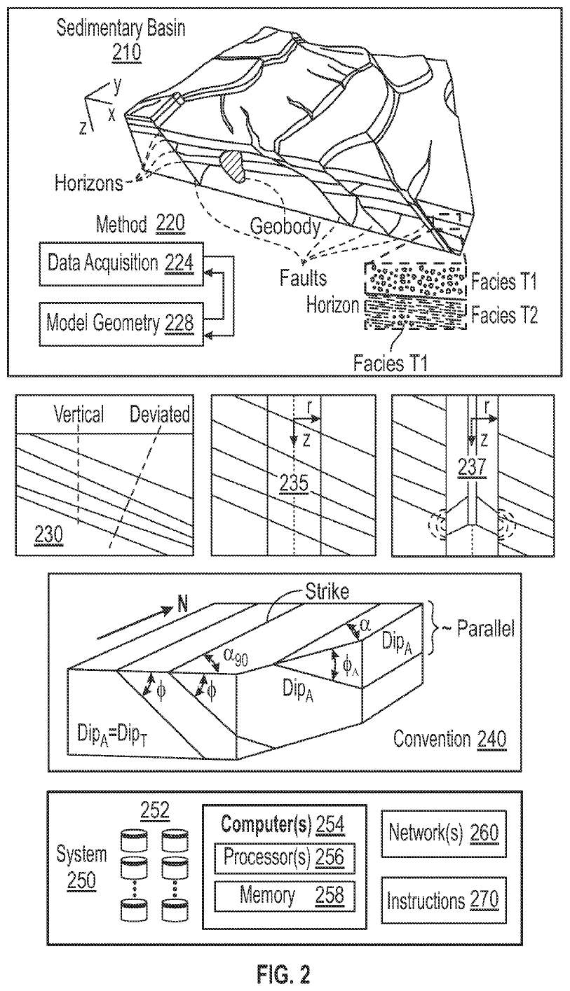

FIG. 2 shows an example of a sedimentary basin 210 (e.g., a geologic environment), an example of a method 220 for model building (e.g., for a simulator, etc.), an example of a formation 230, an example of a borehole 235 in a formation, an example of a convention 240 and an example of a system 250.

As an example, data acquisition, reservoir simulation, petroleum systems modeling, etc. may be applied to characterize various types of subsurface environments, including environments such as those of FIG. 1.

In FIG. 2, the sedimentary basin 210, which is a geologic environment, includes horizons, faults, one or more geobodies and facies formed over some period of geologic time. These features are distributed in two or three dimensions in space, for example, with respect to a Cartesian coordinate system (e.g., x, y and z) or other coordinate system (e.g., cylindrical, spherical, etc.). As shown, the model building method 220 includes a data acquisition block 224 and a model geometry block 228. Some data may be involved in building an initial model and, thereafter, the model may optionally be updated in response to model output, changes in time, physical phenomena, additional data, etc. As an example, data for modeling may include one or more of the following: depth or thickness maps and fault geometries and timing from seismic, remote-sensing, electromagnetic, gravity, outcrop and well log data. Furthermore, data may include depth and thickness maps stemming from facies variations (e.g., due to seismic unconformities) assumed to following geological events (“iso” times) and data may include lateral facies variations (e.g., due to lateral variation in sedimentation characteristics).

To proceed to modeling of geological processes, data may be provided, for example, data such as geochemical data (e.g., temperature, kerogen type, organic richness, etc.), timing data (e.g., from paleontology, radiometric dating, magnetic reversals, rock and fluid properties, etc.) and boundary condition data (e.g., heat-flow history, surface temperature, paleowater depth, etc.).

In basin and petroleum systems modeling, quantities such as temperature, pressure and porosity distributions within the sediments may be modeled, for example, by solving partial differential equations (PDEs) using one or more numerical techniques. Modeling may also model geometry with respect to time, for example, to account for changes stemming from geological events (e.g., deposition of material, erosion of material, shifting of material, etc.).

As shown in FIG. 2, the formation 230 includes a horizontal surface and various subsurface layers. As an example, a borehole may be vertical. As another example, a borehole may be deviated. In the example of FIG. 2, the borehole 235 may be considered a vertical borehole, for example, where the z-axis extends downwardly normal to the horizontal surface of the formation 230. As an example, a tool 237 may be positioned in a borehole, for example, to acquire information. As mentioned, a borehole tool can include one or more sensors that can acquire borehole images via one or more imaging techniques. A data acquisition sequence for such a tool can include running the tool into a borehole with acquisition pads closed, opening and pressing the pads against a wall of the borehole, delivering electrical current into the material defining the borehole while translating the tool in the borehole, and sensing current remotely, which is altered by interactions with the material.

As an example, data can include geochemical data. For example, consider data acquired using X-ray fluorescence (XRF) technology, Fourier transform infrared spectroscopy (FTIR) technology and/or wireline geochemical technology.

As an example, one or more probes may be deployed in a bore via a wireline or wirelines. As an example, a probe may emit energy and receive energy where such energy may be analyzed to help determine mineral composition of rock surrounding a bore. As an example, nuclear magnetic resonance may be implemented (e.g., via a wireline, downhole NMR probe, etc.), for example, to acquire data as to nuclear magnetic properties of elements in a formation (e.g., hydrogen, carbon, phosphorous, etc.).

As an example, lithology scanning technology may be employed to acquire and analyze data. For example, consider the LITHO SCANNER technology marketed by Schlumberger Limited (Houston, Texas). As an example, a LITHO SCANNER tool may be a gamma ray spectroscopy tool.

As an example, a tool may be positioned to acquire information in a portion of a borehole. Analysis of such information may reveal vugs, dissolution planes (e.g., dissolution along bedding planes), stress-related features, dip events, etc. As an example, a tool may acquire information that may help to characterize a fractured reservoir, optionally where fractures may be natural and/or artificial (e.g., hydraulic fractures). Such information may assist with completions, stimulation treatment, etc. As an example, information acquired by a tool may be analyzed using a framework such as the aforementioned TECHLOG framework.

As an example, a workflow may utilize one or more types of data for one or more processes (e.g., stratigraphic modeling, basin modeling, completion designs, drilling, production, injection, etc.). As an example, one or more tools may provide data that can be used in a workflow or workflows that may implement one or more frameworks (e.g., PETREL, TECHLOG, PIPESIM, ECLIPSE, INTERSECT, VISAGE, MANGROVE, etc.).

As to the convention 240 for dip, as shown in FIG. 2, the three-dimensional orientation of a plane can be defined by its dip and strike. Dip is the angle of slope of a plane from a horizontal plane (e.g., an imaginary plane) measured in a vertical plane in a specific direction. Dip may be defined by magnitude (e.g., also known as angle or amount) and azimuth (e.g., also known as direction). As shown in the convention 240 of FIG. 2, various angles ϕ indicate angle of slope downwards, for example, from an imaginary horizontal plane (e.g., flat upper surface); whereas dip refers to the direction towards which a dipping plane slopes (e.g., which may be given with respect to degrees, compass directions, etc.). Another feature shown in the convention of FIG. 2 is strike, which is the orientation of the line created by the intersection of a dipping plane and a horizontal plane (e.g., consider the flat upper surface as being an imaginary horizontal plane).

Some additional terms related to dip and strike may apply to an analysis, for example, depending on circumstances, orientation of collected data, etc. One term is “true dip” (see, e.g., DipT in the convention 240 of FIG. 2). True dip is the dip of a plane measured directly perpendicular to strike (see, e.g., line directed northwardly and labeled “strike” and angle ago) and also the maximum possible value of dip magnitude. Another term is “apparent dip” (see, e.g., DipA in the convention 240 of FIG. 2). Apparent dip may be the dip of a plane as measured in any other direction except in the direction of true dip (see, e.g., ϕ_{A} as DipA for angle α); however, it is possible that the apparent dip is equal to the true dip (see, e.g., ϕ as DipA=DipT for angle ago with respect to the strike). In other words, where the term apparent dip is used (e.g., in a method, analysis, algorithm, etc.), for a particular dipping plane, a value for “apparent dip” may be equivalent to the true dip of that particular dipping plane.

As shown in the convention 240 of FIG. 2, the dip of a plane as seen in a cross-section perpendicular to the strike is true dip (see, e.g., the surface with ϕ as DipA=DipT for angle α₉₀ with respect to the strike). As indicated, dip observed in a cross-section in any other direction is apparent dip (see, e.g., surfaces labeled DipA). Further, as shown in the convention 240 of FIG. 2, apparent dip may be approximately 0 degrees (e.g., parallel to a horizontal surface where an edge of a cutting plane runs along a strike direction).

In terms of observing dip in wellbores, true dip is observed in wells drilled vertically. In wells drilled in any other orientation (or deviation), the dips observed are apparent dips (e.g., which are referred to by some as relative dips). In order to determine true dip values for planes observed in such boreholes, as an example, a vector computation (e.g., based on the borehole deviation) may be applied to one or more apparent dip values.

As mentioned, another term that finds use in sedimentological interpretations from borehole images is “relative dip” (e.g., Dip_{R}). A value of true dip measured from borehole images in rocks deposited in very calm environments may be subtracted (e.g., using vector-subtraction) from dips in a sand body. In such an example, the resulting dips are called relative dips and may find use in interpreting sand body orientation.

A convention such as the convention 240 may be used with respect to an analysis, an interpretation, an attribute, etc. As an example, various types of features may be described, in part, by dip (e.g., sedimentary bedding, faults and fractures, cuestas, igneous dikes and sills, metamorphic foliation, etc.). As an example, dip may change spatially as a layer approaches a geobody. For example, consider a salt body that may rise due to various forces (e.g., buoyancy, etc.). In such an example, dip may trend upward as a salt body moves upward.

Seismic interpretation may aim to identify and/or classify one or more subsurface boundaries based at least in part on one or more dip parameters (e.g., angle or magnitude, azimuth, etc.). As an example, various types of features (e.g., sedimentary bedding, faults and fractures, cuestas, igneous dikes and sills, metamorphic foliation, etc.) may be described at least in part by angle, at least in part by azimuth, etc.

As an example, equations may be provided for petroleum expulsion and migration, which may be modeled and simulated, for example, with respect to a period of time. Petroleum migration from a source material (e.g., primary migration or expulsion) may include use of a saturation model where migration-saturation values control expulsion. Determinations as to secondary migration of petroleum (e.g., oil or gas), may include using hydrodynamic potential of fluid and accounting for driving forces that promote fluid flow. Such forces can include buoyancy gradient, pore pressure gradient, and capillary pressure gradient.

As shown in FIG. 2, the system 250 includes one or more information storage devices 252, one or more computers 254, one or more networks 260 and instructions 270. As to the one or more computers 254, each computer may include one or more processors (e.g., or processing cores) 256 and memory 258 for storing instructions, for example, consider the instructions 270 as including instructions executable by at least one of the one or more processors. As an example, a computer may include one or more network interfaces (e.g., wired or wireless), one or more graphics cards (e.g., one or more GPUs, etc.), a display interface (e.g., wired or wireless), etc. As an example, imagery such as surface imagery (e.g., satellite, geological, geophysical, etc.) may be stored, processed, communicated, etc. As an example, data may include SAR data, GPS data, etc. and may be stored, for example, in one or more of the storage devices 252. As an example, the system 250 may be local, remote or in part local and in part remote. As to remote resources, consider one or more cloud-based resources (e.g., as part of a cloud platform, etc.).

As an example, the instructions 270 may include instructions (e.g., stored in memory) executable by one or more processors to instruct the system 250 to perform various actions. As an example, the system 250 may be configured such that the instructions 270 provide for establishing one or more aspects of the workspace framework 110 of FIG. 1. As an example, one or more methods, techniques, etc. may be performed at least in part via instructions, which may be, for example, instructions of the instructions 270 of FIG. 2.

As an example, a framework can include various components. For example, a framework can include one or more components for prediction of reservoir performance, one or more components for optimization of an operation or operations, one or more components for control of production engineering operations, etc. As an example, a framework can include components for prediction of reservoir performance, optimization and control of production engineering operations performed at one or more reservoir wells. Such a framework may, for example, allow for implementation of various methods. For example, consider an approach that allows for a combination of physics-based and data-driven methods for modeling and forecasting a reservoir production.

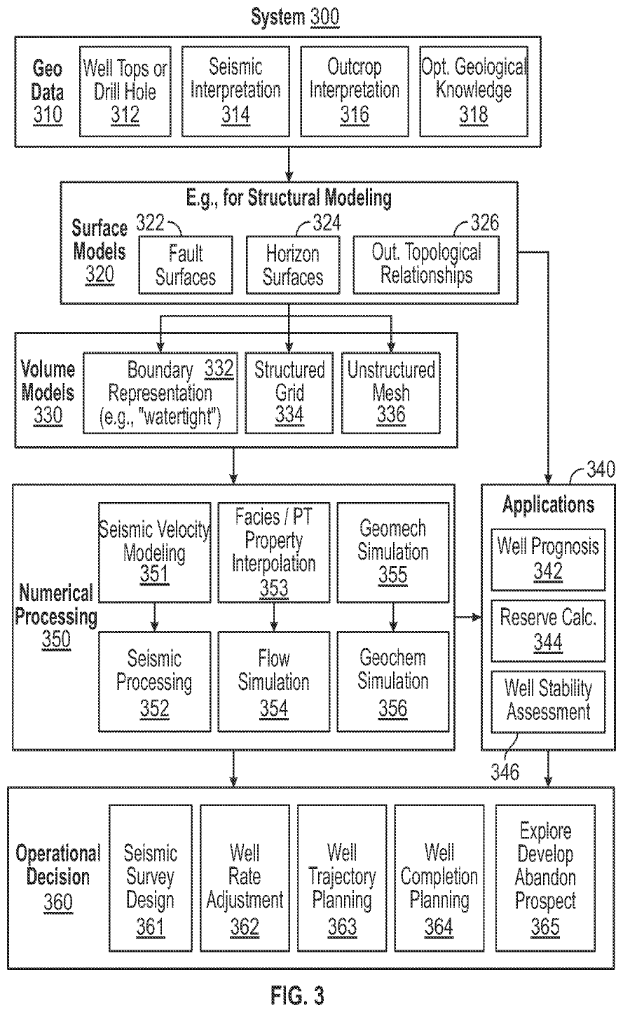

FIG. 3 shows an example of a system 300 that includes a geological/geophysical data block 310, a surface models block 320 (e.g., for one or more structural models), a volume modules block 330, an applications block 340, a numerical processing block 350 and an operational decision block 360. As shown in the example of FIG. 3, the geological/geophysical data block 310 can include data from well tops or drill holes 312, data from seismic interpretation 314, data from outcrop interpretation and optionally data from geological knowledge. As to the surface models block 320, it may provide for creation, editing, etc. of one or more surface models based on, for example, one or more of fault surfaces 322, horizon surfaces 324 and optionally topological relationships 326. As to the volume models block 330, it may provide for creation, editing, etc. of one or more volume models based on, for example, one or more of boundary representations 332 (e.g., to form a watertight model), structured grids 334 and unstructured meshes 336.

As shown in the example of FIG. 3, the system 300 may allow for implementing one or more workflows, for example, where data of the data block 310 are used to create, edit, etc. one or more surface models of the surface models block 320, which may be used to create, edit, etc. one or more volume models of the volume models block 330. As indicated in the example of FIG. 3, the surface models block 320 may provide one or more structural models, which may be input to the applications block 340. For example, such a structural model may be provided to one or more applications, optionally without performing one or more processes of the volume models block 330 (e.g., for purposes of numerical processing by the numerical processing block 350). Accordingly, the system 300 may be suitable for one or more workflows for structural modeling (e.g., optionally without performing numerical processing per the numerical processing block 350).

As to the applications block 340, it may include applications such as a well prognosis application 342, a reserve calculation application 344 and a well stability assessment application 346. As to the numerical processing block 350, it may include a process for seismic velocity modeling 351 followed by seismic processing 352, a process for facies and petrophysical property interpolation 353 followed by flow simulation 354, and a process for geomechanical simulation 355 followed by geochemical simulation 356. As indicated, as an example, a workflow may proceed from the volume models block 330 to the numerical processing block 350 and then to the applications block 340 and/or to the operational decision block 360. As another example, a workflow may proceed from the surface models block 320 to the applications block 340 and then to the operational decisions block 360 (e.g., consider an application that operates using a structural model).

In the example of FIG. 3, the operational decisions block 360 may include a seismic survey design process 361, a well rate adjustment process 352, a well trajectory planning process 363, a well completion planning process 364 and a process for one or more prospects, for example, to decide whether to explore, develop, abandon, etc. a prospect.

Referring again to the data block 310, the well tops or drill hole data 312 may include spatial localization, and optionally surface dip, of an interface between two geological formations or of a subsurface discontinuity such as a geological fault; the seismic interpretation data 314 may include a set of points, lines or surface patches interpreted from seismic reflection data, and representing interfaces between media (e.g., geological formations in which seismic wave velocity differs) or subsurface discontinuities; the outcrop interpretation data 316 may include a set of lines or points, optionally associated with measured dip, representing boundaries between geological formations or geological faults, as interpreted on the earth surface; and the geological knowledge data 318 may include, for example knowledge of the paleo-tectonic and sedimentary evolution of a region.

As to a structural model, it may be, for example, a set of gridded or meshed surfaces representing one or more interfaces between geological formations (e.g., horizon surfaces) or mechanical discontinuities (fault surfaces) in the subsurface. As an example, a structural model may include some information about one or more topological relationships between surfaces (e.g. fault A truncates fault B, fault B intersects fault C, etc.).

As to the one or more boundary representations 332, they may include a numerical representation in which a subsurface model is partitioned into various closed units representing geological layers and fault blocks where an individual unit may be defined by its boundary and, optionally, by a set of internal boundaries such as fault surfaces.

As to the one or more structured grids 334, it may include a grid that partitions a volume of interest into different elementary volumes (cells), for example, that may be indexed according to a pre-defined, repeating pattern. As to the one or more unstructured meshes 336, it may include a mesh that partitions a volume of interest into different elementary volumes, for example, that may not be readily indexed following a pre-defined, repeating pattern (e.g., consider a Cartesian cube with indexes I, J, and K, along x, y, and z axes).

As to the seismic velocity modeling 351, it may include calculation of velocity of propagation of seismic waves (e.g., where seismic velocity depends on type of seismic wave and on direction of propagation of the wave). As to the seismic processing 352, it may include a set of processes allowing identification of localization of seismic reflectors in space, physical characteristics of the rocks in between these reflectors, etc.

As to the facies and petrophysical property interpolation 353, it may include an assessment of type of rocks and of their petrophysical properties (e.g. porosity, permeability), for example, optionally in areas not sampled by well logs or coring. As an example, such an interpolation may be constrained by interpretations from log and core data, and by prior geological knowledge.

As to the flow simulation 354, as an example, it may include simulation of flow of hydro-carbons in the subsurface, for example, through geological times (e.g., in the context of petroleum systems modeling, when trying to predict the presence and quality of oil in an un-drilled formation) or during the exploitation of a hydrocarbon reservoir (e.g., when some fluids are pumped from or into the reservoir).

As to geomechanical simulation 355, it may include simulation of the deformation of rocks under boundary conditions. Such a simulation may be used, for example, to assess compaction of a reservoir (e.g., associated with its depletion, when hydrocarbons are pumped from the porous and deformable rock that composes the reservoir). As an example a geomechanical simulation may be used for a variety of purposes such as, for example, prediction of fracturing, reconstruction of the paleo-geometries of the reservoir as they were prior to tectonic deformations, etc.

As to geochemical simulation 356, such a simulation may simulate evolution of hydrocarbon formation and composition through geological history (e.g., to assess the likelihood of oil accumulation in a particular subterranean formation while exploring new prospects).

As to the various applications of the applications block 340, the well prognosis application 342 may include predicting type and characteristics of geological formations that may be encountered by a drill-bit, and location where such rocks may be encountered (e.g., before a well is drilled); the reserve calculations application 344 may include assessing total amount of hydrocarbons or ore material present in a subsurface environment (e.g., and estimates of which proportion can be recovered, given a set of economic and technical constraints); and the well stability assessment application 346 may include estimating risk that a well, already drilled or to-be-drilled, will collapse or be damaged due to underground stress.

As to the operational decision block 360, the seismic survey design process 361 may include deciding where to place seismic sources and receivers to optimize the coverage and quality of the collected seismic information while minimizing cost of acquisition; the well rate adjustment process 362 may include controlling injection and production well schedules and rates (e.g., to maximize recovery and production); the well trajectory planning process 363 may include designing a well trajectory to maximize potential recovery and production while minimizing drilling risks and costs; the well trajectory planning process 364 may include selecting proper well tubing, casing and completion (e.g., to meet expected production or injection targets in specified reservoir formations); and the prospect process 365 may include decision making, in an exploration context, to continue exploring, start producing or abandon prospects (e.g., based on an integrated assessment of technical and financial risks against expected benefits).

The system 300 can include and/or can be operatively coupled to a system such as the system 100 of FIG. 1. For example, the workspace framework 110 may provide for instantiation of, rendering of, interactions with, etc., the graphical user interface (GUI) 120 to perform one or more actions as to the system 300. In such an example, access may be provided to one or more frameworks (e.g., DRILLPLAN, PETREL, TECHLOG, PIPESIM, ECLIPSE, INTERSECT, VISAGE, MANGROVE, etc.). One or more frameworks may provide for geo data acquisition as in block 310, for structural modeling as in block 320, for volume modeling as in block 330, for running an application as in block 340, for numerical processing as in block 350, for operational decision making as in block 360, etc.

The PIPESIM framework can be executed to perform various steady-state flow assurance workflows, for example, for front-end system design, production operations, etc. Flow assurance capabilities can help assure fluid transport such as from sizing of facilities, pipelines, and lift systems, to ensuring effective liquids and solids management, to well and pipeline integrity. The PIPESIM framework can provide for dynamic analysis where, for example, a PIPESIM-to-OLGA converter tool may be implemented for rapid conversion of models. Shared heat transfer, multiphase flow, and fluid behavior methodologies help to ensure data quality and consistency between the steady-state and transient analyses.

As an example, a framework may provide for electric submersible pump (ESP) surface power calculations. For example, a framework simulator can calculate the ESP power consumption at surface conditions where an installed motor and cable in well are modeled. As an example, a framework may provide for gas lift modeling. In such an example, the framework may access a gas lift valves catalog or the Valve Performance Clearinghouse (VPC) catalog from Louisiana State University for gas lift modeling. As an example, a framework may provide for annulus flow in surface pipes modeling. In such an example, a workflow may involve modeling multilateral completions, configurations for SAGD operations, etc. As an example, a framework may provide for prediction of gas lift multi-pointing. Gas lift multipointing is a nondesirable condition that can be modeled using a gas lift diagnostics task. A framework such as the PIPESIM framework can predict such a condition in pressure and temperature and system analysis tasks. As an example, a framework may provide for generation of erosion and corrosion risk indicators. For example, consider generation of risk indicators for erosional velocity ratio (EVR) and corrosion rate, which may be generated based on user-defined risk ranking limits from negligible to severe. In such an example, results may be visualized using a color gradient on a GIS canvas.

As an example, a framework may include various toolkit features. For example, consider Python toolkit features. Such toolkit features can provide extensibility for one or more additional functionalities for a framework or frameworks.

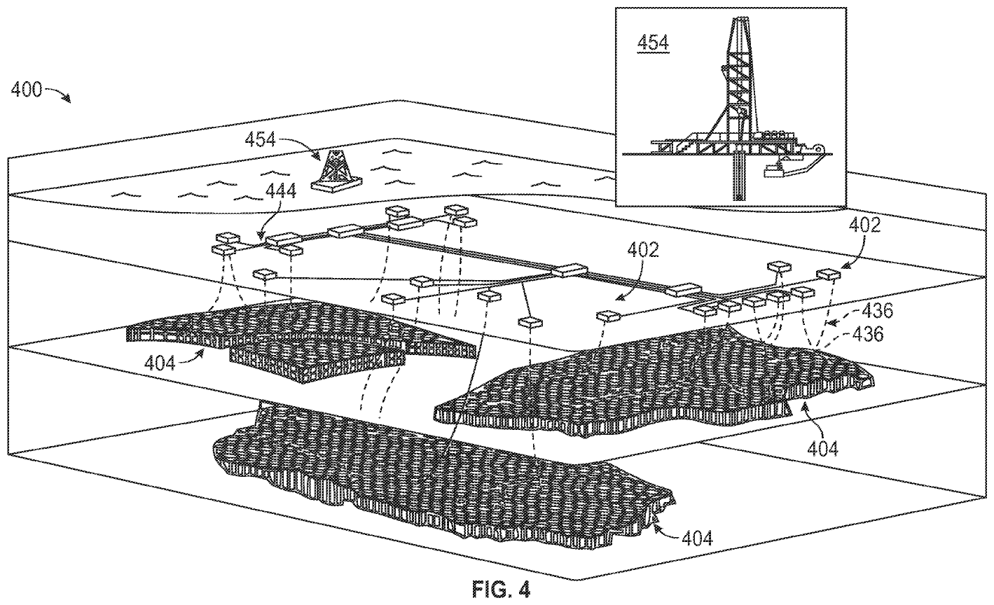

FIG. 4 shows an example of a geologic environment 400 as including various types of equipment and features. As shown, the geologic environment 400 includes a plurality of wellsites 402, which may be operatively connected to a processing facility. In the example of FIG. 4, individual wellsites 402 can include equipment that can form individual wellbores 436. Such wellbores can extend through subterranean formations including one or more reservoirs 404. Such reservoirs 404 can include fluids, such as hydrocarbons. As an example, wellsites can draw fluid from one or more reservoirs and pass them to one or more processing facilities via one or more surface networks 444. As an example, a surface network can include tubing and control mechanisms for controlling flow of fluids from a wellsite to a processing facility. In the example of FIG. 4, a rig 454 is shown, which may be an offshore rig or an onshore rig. As an example, a rig can be utilized to drill a borehole that can be completed to be a wellbore where the wellbore can be in fluid communication with a reservoir such that fluid may be produced from the reservoir.

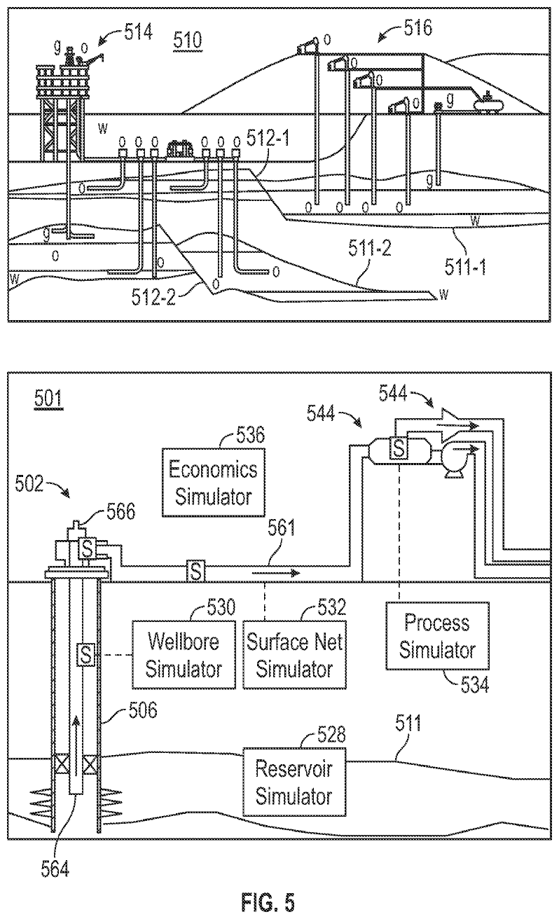

FIG. 5 shows an example of portion of a geologic environment 501 and an example of a larger portion of a geologic environment 510. As shown, a geologic environment can include one or more reservoirs 511-1 and 511-2, which may be faulted by faults 512-1 and 512-2 and which may include oil (o), gas (g) and/or water (w). FIG. 5 also shows some examples of offshore equipment 514 for oil and gas operations related to the reservoirs 511-1 and 511-2 and onshore equipment 516 for oil and gas operations related to the reservoir 511-1. As an example, a system may be implemented for operations associated with one or more of such reservoirs.

As to the geologic environment 501, FIG. 5 shows a schematic view where the geologic environment 501 can include various types of equipment. As shown in FIG. 5, the environment 501 can includes a wellsite 502 and a fluid network 544. In the example of FIG. 5, the wellsite 502 includes a wellbore 506 extending into earth as completed and prepared for production of fluid from a reservoir 511 (e.g., one of the reservoirs 511-1 or 511-2).

In the example of FIG. 5, wellbore production equipment 564 extends from a wellhead 566 of the wellsite 502 and to the reservoir 511 to draw fluid to the surface. As shown, the wellsite 502 is operatively connected to the fluid network 544 via a transport line 561. As indicated by various arrows, fluid can flow from the reservoir 511, through the wellbore 506 and onto the fluid network 544. Fluid can then flow from the fluid network 544, for example, to one or more fluid processing facilities.

In the example of FIG. 5, sensors (S) are located, for example, to monitor various parameters during operations. The sensors (S) may measure, for example, pressure, temperature, flowrate, composition, and other parameters of the reservoir, wellbore, gathering network, process facilities and/or other portions of an operation. As an example, the sensors (S) may be operatively connected to a surface unit (e.g., to instruct the sensors to acquire data, to collect data from the sensors, etc.).

In the example of FIG. 5, a surface unit can include computer facilities, such as a memory device, a controller, one or more processors, and display unit (e.g., for managing data, visualizing results of an analysis, etc.). As an example, data may be collected in the memory device and processed by the processor(s) (e.g., for analysis, etc.). As an example, data may be collected from the sensors (S) and/or by one or more other sources. For example, data may be supplemented by historical data collected from other operations, user inputs, etc. As an example, analyzed data may be used in a decision-making process.

As an example, a transceiver may be provided to allow communications between a surface unit and one or more pieces of equipment in the environment 501. For example, a controller may be used to actuate mechanisms in the environment 501 via the transceiver, optionally based on one or more decisions of a decision-making process. In such a manner, equipment in the environment 501 may be selectively adjusted based at least in part on collected data. Such adjustments may be made, for example, automatically based on computer protocol, manually by an operator or both. As an example, one or more well plans may be adjusted (e.g., to select optimum operating conditions, to avoid problems, etc.).

To facilitate data analyses, one or more simulators may be implemented (e.g., optionally via the surface unit or other unit, system, etc.). As an example, data fed into one or more simulators may be historical data, real time data or combinations thereof. As an example, simulation through one or more simulators may be repeated or adjusted based on the data received.

In the example of FIG. 5, simulators can include a reservoir simulator 528, a wellbore simulator 530, a surface network simulator 532, a process simulator 534 and an economics simulator 536. As an example, the reservoir simulator 528 may be configured to solve for hydrocarbon flow rate through a reservoir and into one or more wellbores. As an example, the wellbore simulator 530 and surface network simulator 532 may be configured to solve for hydrocarbon flow rate through a wellbore and a surface gathering network of pipelines. As to the process simulator 534, it may be configured to model a processing plant where fluid containing hydrocarbons is separated into its constituent components (e.g., methane, ethane, propane, etc.), for example, and prepared for further distribution (e.g., transport via road, rail, pipe, etc.) and optionally sale. As an example, the economics simulator 536 may be configured to model costs associated with at least part of an operation. For example, consider MERAK framework (Schlumberger Limited, Houston, Texas), which may provide for economic analyses.

As an example, a system can include and/or be operatively coupled to one or more of the simulators 528, 530, 532, 534 and 536 of FIG. 5. As an example, such simulators may be associated with frameworks and/or may be considered tools (see, e.g., the system 100 of FIG. 1, etc.).

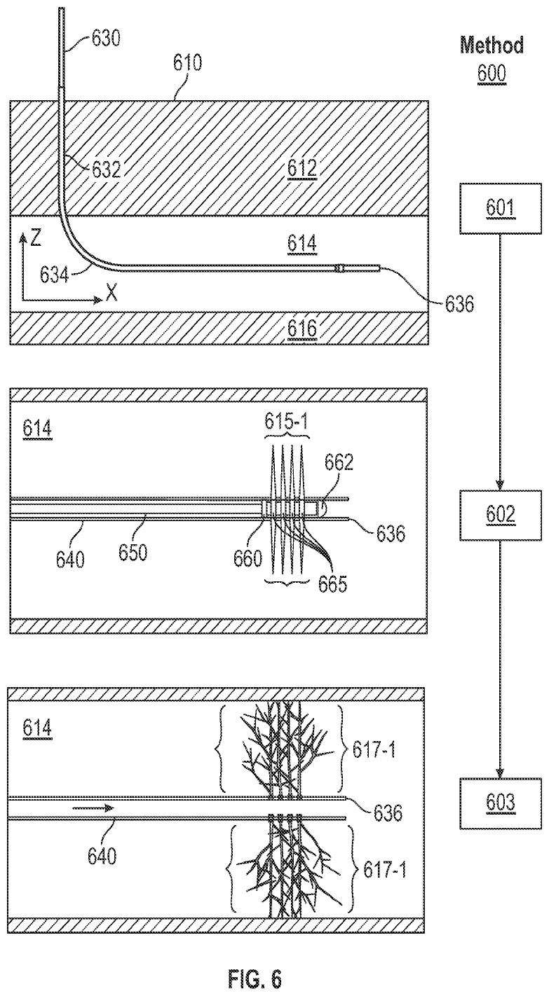

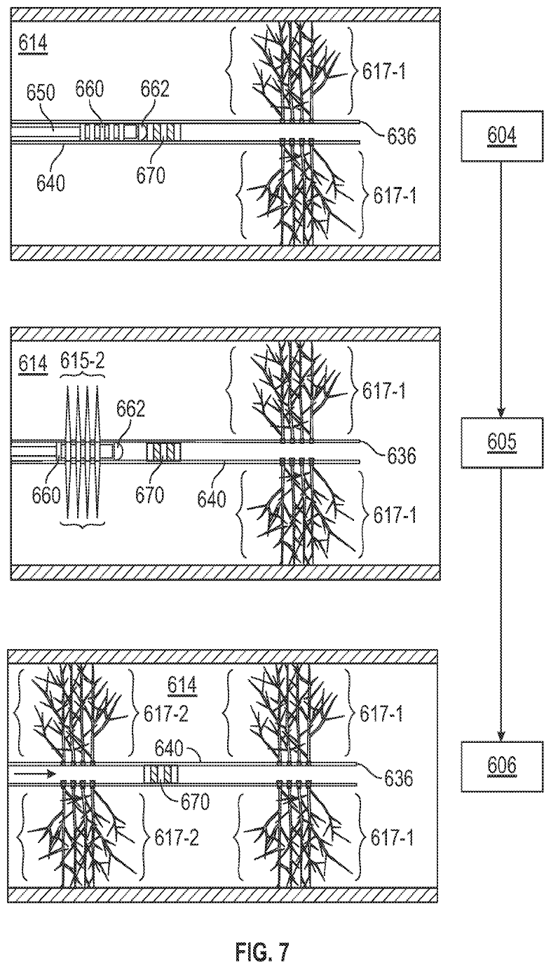

FIGS. 6 and 7 show an example of a method 600 that includes generating fractures. As shown, the method 600 can include various operational blocks such as one or more of the blocks 601, 602, 603, 604, 605 and 606. The block 601 may be a drilling block that includes drilling into a formation 610 that includes layers 612, 614 and 616 to form a bore 630 with a kickoff 632 to a portion defined by a heel 634 and a toe 636, for example, within the layer 614.

As illustrated with respect to the block 602, the bore 630 may be at least partially cased with casing 640 into which a string or line 650 may be introduced that carries a perforator 660. As shown, the perforator 660 can include a distal end 662 and charge positions 665 associated with activatable charges that can perforate the casing 640 and form channels 615-1 in the layer 614. Next, per the block 603, fluid may be introduced into the bore 630 between the heel 634 and the toe 636 where the fluid passes through the perforations in the casing 640 and into the channels 615-1. Where such fluid is under pressure, the pressure may be sufficient to fracture the layer 614, for example, to form fractures 617-1. In the block 603, the fractures 617-1 may be first stage fractures, for example, of a multistage fracturing operation.

Per the block 604, additional operations are performed for further fracturing of the layer 614. For example, a plug 670 may be introduced into the bore 630 between the heel 634 and the toe 636 and positioned, for example, in a region between first stage perforations of the casing 640 and the heel 634. Per the block 605, the perforator 660 may be activated to form additional perforations in the casing 640 (e.g., second stage perforations) as well as channels 615-2 in the layer 614 (e.g., second stage channels). Per the block 606, fluid may be introduced while the plug 670 is disposed in the bore 630, for example, to isolate a portion of the bore 630 such that fluid pressure may build to a level sufficient to form fractures 617-2 in the layer 614 (e.g., second stage fractures).

In a method such as the method 600 of FIGS. 6 and 7, it may be desirable that a plug (e.g., the plug 670) includes properties suited to one or more operations. Properties of a plug may include mechanical properties (e.g., sufficient strength to withstand pressure associated with fracture generation, etc.) and may include one or more other types of properties (e.g., chemical, electrical, etc.). As an example, it may be desirable that a plug degrades, that a plug seat degrades, that at least a portion of a borehole tool degrades, etc. For example, a plug may be manufactured with properties such that the plug withstands, for a period of time, conditions associated with an operation and then degrades (e.g., when exposed to one or more conditions). In such an example, where the plug acts to block a passage for an operation, upon degradation, the passage may become unblocked, which may allow for one or more subsequent operations.

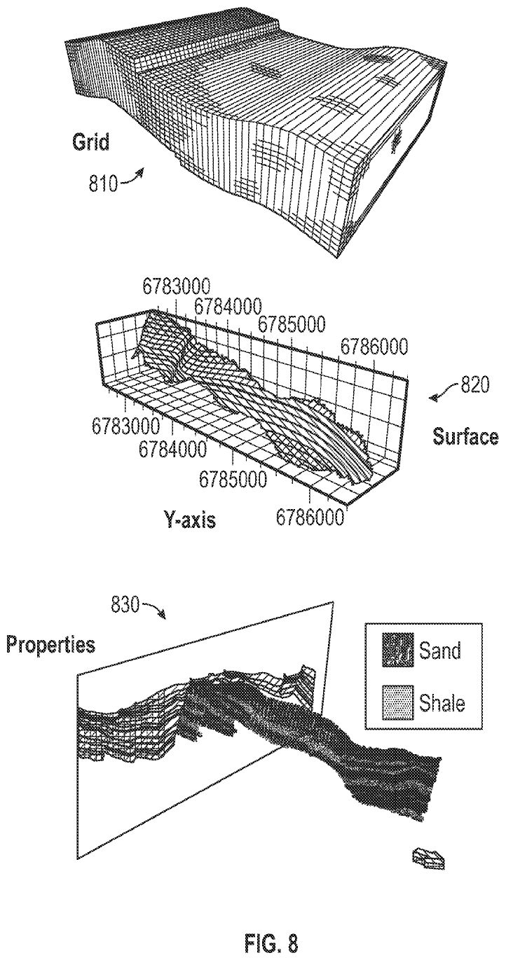

FIG. 8 shows an example of a grid 810, a surface 820 and properties 830. In the example of FIG. 8, the properties 830 can be assigned to various grid cells of the grid 810, various surfaces defined by or within the grid 810, etc.

As an example, a method can include performing one or more progressive failure techniques for sand and/or other solid production volume, for example, with rates estimation. In such an example, the method may be employed using one or more numerical techniques. For example, consider using a finite element technique (e.g., the finite element method (FEM)), a volume technique, a finite difference technique, a point-based technique, a “meshless” technique, etc.

As an example, a method can include estimating the volume of producible sand/solid (e.g., sandstone, carbonate, turbidite, etc.) during hydrocarbon production using one or more numerical techniques. Such a method can include employing a cell “virtual removal” technique, for example, without re-meshing nor actual removal of a cell. For example, consider assigning one or more parameters to one or more cells, which may be performed in a dynamic method. As an example, consider assigning a null elastic property to a cell and progressively transferring stress until stabilization. Such a technique may be applied to a tunnel/opening process in a subsurface region (e.g., consider a borehole, a perforation, a hydraulic fracture or other geometry for one or more types of reservoirs (e.g., sandstone, carbonate, turbidite, etc.).

As an example, a method can include constructing a 1D, 2D, and/or 3D mechanical earth model (MEM); generating an appropriate numerical grid and meshing around a borehole and/or one or more perforation tunnels or geometry of a fabric face where production is expected to occur to carry hydrocarbon fluid (e.g., to surface, etc.); computing stress-strain evolution and detecting failure(s) and/or softening and along with removal of a cell using one or more criteria (e.g., virtual removal); recording the removed cell identifier (e.g., cell number, etc.) and computing a volume of sand/solid and its rate(s).

As an example, a method may be applied in the field of geosciences, engineering, etc. Such a method may allow a better estimation of potential sand/solid production volume and rates to assist in one or more of completion and drawdown management for one or more types of fluid reservoirs (e.g., hydrocarbon, gas, water, etc.).

Severity of sand production rate modeling has been attempted via analytical and semi-analytical models. Bratli and Risnes (1981) implemented formation of arching during sand production and its stability via an analytical model, validated through laboratory experiment, where the root for formation collapse was deemed due to fracturing mechanics. See Bratli, Rolf K. and Risnes, Rasmus. 1981. Stability and Failure of Sand Arches (in en). Society of Petroleum Engineers Journal 21 (02): 236-248. In particular, for the total collapse to manifest, the radius of the plastic Coulomb zone is to be close to a geometrical limit. However, such an approach can be limited as considering overburden stress alone and ignoring other tectonic horizontal stresses.

An approach by Geilikman et al. (1994) added a mass balance to solve the relationship between rock yielding and cumulative sand production, with purported honoring of both shear and tensile failure in the formulation. See Geilikman, M. B., Dusseault, M. B., and Dullien, F. A. 1994. Sand Production as a Viscoplastic Granular Flow. Proc., SPE Formation Damage Control Symposium, Jan. 1, 1994, 10. SPE-27343-MS.

However, the model was analytical where stress stabilization after failure is not studied (e.g., demanding a numerical model). Weingarten and Perkins (1995) reported that the Bratli and Risnes (1981) method was too conservative where the theory of flow into the hemispherical might not be valid as flow into the perforation may be at the tips such that a damage mechanism demands further understanding. Volonté et al. (2013) attempted to model sand production via 3D FEM coupled with fluid flow; however, focused on onset failure analysis and not sand production volume. See Volonté, Giorgio, Scarfato, Francesco, and Brignoli, Marco. 2013. Sand Prediction: A Practical Finite-Element 3D Approach for Real Field Applications (in english). SPE Production & Operations 28 (01): 95-108. Mohamad-Hussein and Ni (2018) formulated an elasto-plastic damage model for various mechanical features for porous sandstone where, akin to Volonté et al. (2013), the modified Mohr-Coulomb damaged constitutive model was coupled between 3D FEM and fluid flow where sanding rates were computed based on plastic strain cutoff and not actual rock failure (post-failure stress stabilization was not considered). See Mohamad-Hussein, Assef and Ni, Qinglai. 2018. Numerical modeling of onset and rate of sand production in perforated wells (in en). Journal of Petroleum Exploration and Production Technology. Garolera et al. (2020) utilized a zero-thickness interface finite elements for sanding prediction analysis to simulate grain dislocation complexity; however, such an approach tends to be quite complex and time consuming while also assuming that the rock is elastic with relatively large grain size, which tends to have less risk for sand production. See Garolera, Daniel, Carol, Ignacio, and Papanastasiou, Panos. 2020. Application of zero-thickness interface elements to sanding prediction analysis. Journal of Petroleum Science and Engineering 190: 107052.

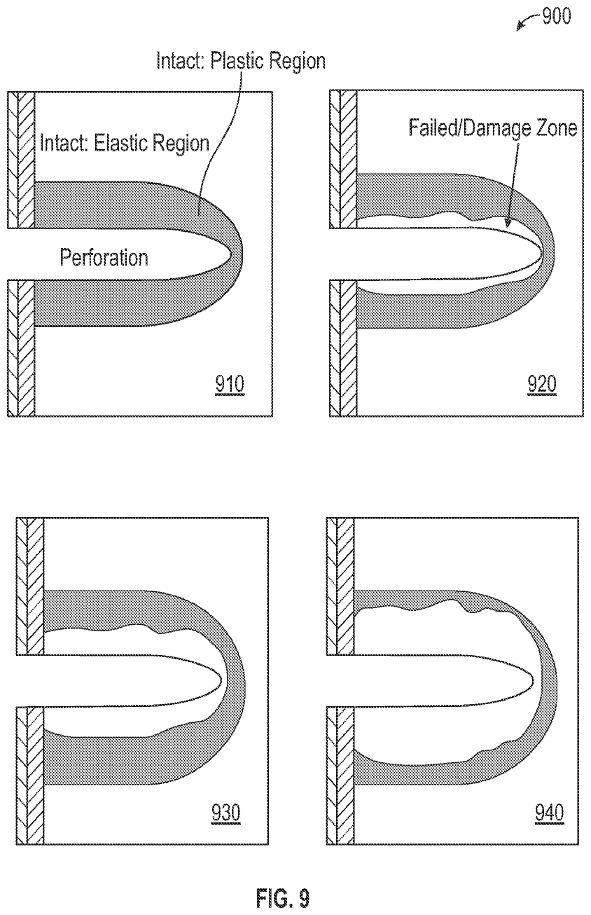

FIG. 9 shows an example of a process 900 for rock failure progression via graphics 910, 920, 930 and 940. As shown, rock failure can lead to cavity formation, which is a progressive process that occurs as rock loosens away from a perforation tunnel. Based on intensity of rock damage, various zones (e.g., regions) can exist around a perforation tunnel or borehole. For example, consider an intact rock region as a region where the formation is undamaged and still intact; a plastic/yield region as a lightly damaged region with fewer micro-cracks where the rock still can hold the stress without any failure (e.g., stress-bearing capacity is not substantially reduced, etc.); and a failed/damaged zone that represents the zone around the perforation that lost stress-bearing capacity and failure or dislocated where rock mass in this zone may be removed, for example, it may be spalled off from the perforation wall to thereby lead to sand/solid production (e.g., a volume of sand/solid).

As an example, a method may be implemented as part of a computational framework, for example, as an integral part, via an application programming interface (API), etc. For example, consider implementation with the PETREL-RG powered by VISAGE FEM engine where a failed cell can be removed from intact rock allowing for stress and cavity stabilization for each load increment. As mentioned, one or more other types of numerical techniques may be utilized (e.g., FEM, FD, etc., optionally including pre- and/or post-processors).

As an example, a method can make rock of a cell unable to hold a further strain and/or stresses increment (e.g., failed or softened) where the cell has been deactivated by assignment of one or more null elastic properties, which, as explained, can provide for maintaining the cell in a grid (e.g., a mesh, etc.) without having to remove the cell and/or re-grid/re-mesh, which can be computationally intensive and time consuming, particularly where quality control measures are to be implemented that may trigger further re-gridding/re-meshing.

As explained, a method can provide for simulating an analog of spalling off of formation rock into a wellbore. As an example, cell removal/deactivation can induce further stress redistribution around a cavity. In such an example, the stress redistribution can then be calculated where, for example, if the stress redistribution around the removed cell is substantial as to risk of violating a failure criterion at the next loading step, then a failed cell(s) at the next step can be removed. Such a process may be repeated until an end of a schedule of sample loading. After completion of model preparation, a model can then be simulated for progressive cavity failure and stabilization.

In various trials, the VISAGE framework's FEM engine is utilized with coupling to developed code to perform the failed cell “removal” and record an amount of a failed cell that can be translated into volume of produced sand/solid.

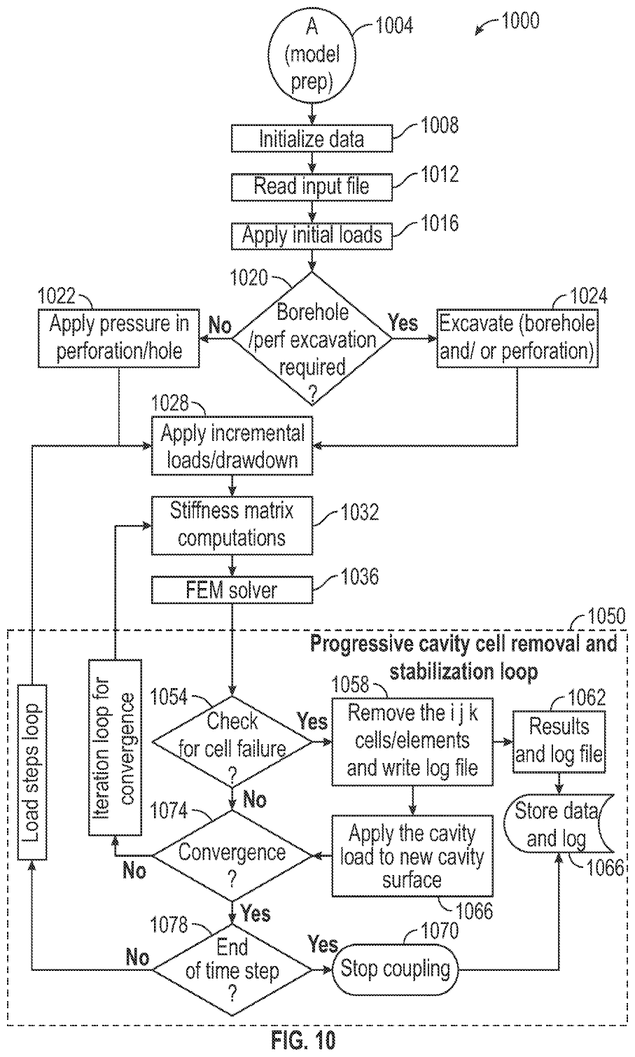

FIG. 10 shows an example of a method 1000 that includes various blocks, which include actions, decisions, etc. As shown, various loops can exist. A dashed box encompasses various aspects of a cell “removal” approach that can provide for volume estimates as to sand/solids production, etc. As shown in the method 1000 of FIG. 10, various features can interact with the VISAGE framework for analyzing computed numerical stress, strain, yield, and failure result if the cell has failed and the removal process and reassigning of pressure load to a new cavity boundary.

At blocks 1004 and 1008, model preparation can involve generation of a model and mesh for GRID cells and initialization, for example, via population of mechanical properties such as Young's Modulus, Poisson's Ratio, UCS, TSTR, FANG, etc. As an example, a model may be cylindrical shape for laboratory test and may be block shape for field case study. As an example, various boundary conditions can be applied, for example, in terms of degree of freedom and load direction.

At blocks 1012 and 1016, one or more input files may be accessed and various loads applied. For example, consider prescribing boundary loads and pore pressure for initial stress conditions.

At a decision block 1020, a decision can be made as to borehole/perforation excavation. For example, consider an excavation process by removing grid cells for a borehole and/or a perforation tunnel and allowing stress distribution around the opening due to far-field stress prior to production for a field case. As to a laboratory model case, the excavation is not necessarily required as the perforation may already be in place at the beginning of the stress loading. The decision block 1020 can, per a “no” branch, proceed to a pressure application block 1022 or, per a “yes” branch, proceed to an excavate block 1024.

At an increment block 1028, the method 1000 can include applying a load increment to the model and outputting displacement stress, strain, yield and failure value. As shown, a block 1032 can provide for stiffness matrix computations and a block 1036 can provide for calling a numerical solver (e.g., FEM solver, etc.).

As shown, the method 1000 can enter the block 1050, which can encompass various sub-blocks. As shown, a decision block 1054 can check for cell failure. Such a block may perform an audit of various individual cells where, if a cell reaches failure (f>=0) or one or more selected criteria such as equivalent plastic strain, volumetric strain or residual stress, per a “yes” branch, the method 1000 can proceed to a “removal” block 1058 that can provide for removing the cell and recording a quantity of a cell or cells removed and corresponding i,j,k coordinates. In such an example, an audit can be conducted on the stress state using one or more types of constitutive models.

As shown, the block 1058 can proceed to a file block 1062 and to an application block 1066, which can provide for applying the cavity load to a new cavity surface. The file block 1062 can proceed to a storage block 1066, which may be fed by one or more other blocks such as a stop coupling block 1070, which can occur after convergence per a decision block 1074 and end of time stepping (e.g., time increments) per a decision block 1078. As shown, the decision block 1074 can be in an iterative loop that seeks convergence (e.g., exiting the block 1050) and the decision block 1078 can be in a loop that provides for load increments. As explained, the method 1000 can provide for progressive cavity failure and cell “removal” and stabilization.

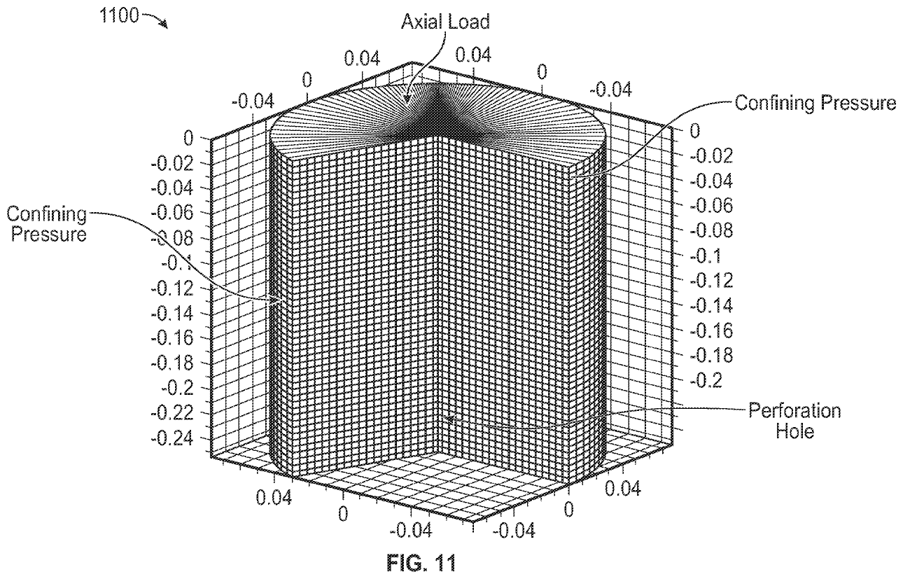

FIG. 11 shows an example of a cylindrical model 1100 that includes an axial load with respect to rock with a perforation hole where confining pressure can be modeled. FIG. 11 illustrates a manner for FEM numerical model simulation meshing, and grid setup with boundary conditions. The model 1100 can be utilized for various example trials, noting that axial load and confining pressure boundary condition(s) can be adjusted accordingly, for example, to laboratory test results, etc. In the example of FIG. 11, progressive cavity failure and stress stabilization by grid cell removal can be activated during a simulation. In such an example, a failed and removed grid cell can be recorded along with the number of cells including the volume of cells.

As an example, cumulative sand/solid mass may be calculated using equation (1) below:

$${W}_{solid} = \sum {n}_{i \cdot j \cdot k} \times {V}_{i , j , k} \times {ρ}_{solid} \times Porosity \qquad ( 1 )$$

where W_{solid} is mass of the sand/solid n_{i,j,k} is number of failure cell, V_{i,j,k} is volume of the cell and ρ_{solid} is density of the sold grains.

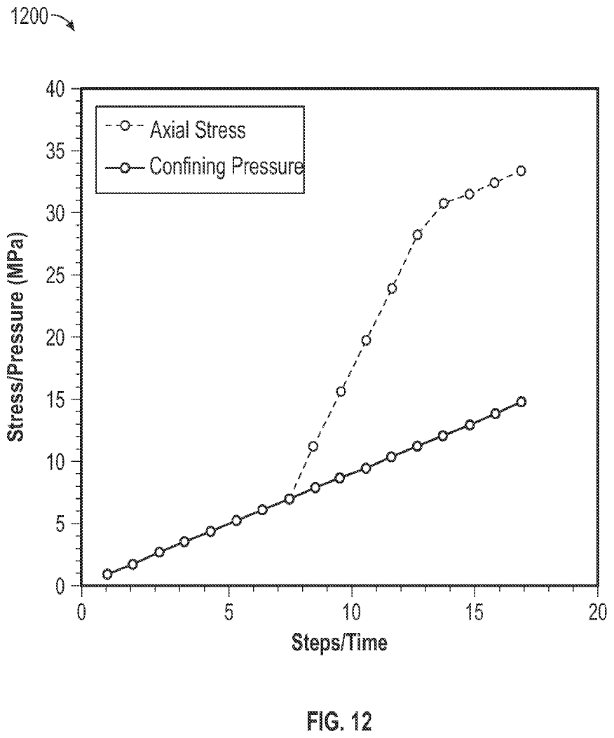

FIG. 12 shows an example plot 1200 as to a stress/pressure loading scheme for Sample 1 (e.g., axial stress and confining pressure). In this example, the sample was loaded triaxially (e.g., axial stress>radial stress); noting that a similar loading profile is implemented during numerical simulation.

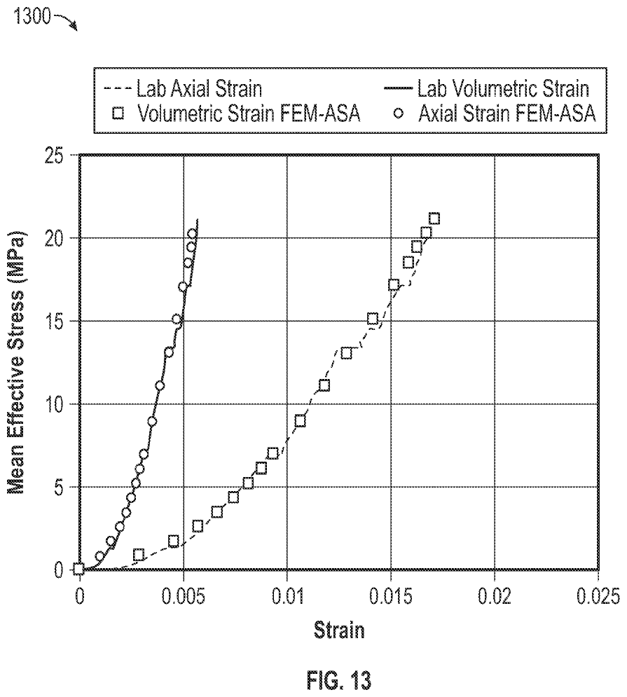

FIG. 13 shows an example plot 1300 of laboratory measured stress and strain; noting that measurements were recorded at the top and edge of the sample in the perforated hole. The plot 1300 also shows FEM modelled stress and strain. The stress and strain from the laboratory measurements have been compared with the numerical modelling. As the results of the comparison between the laboratory measurement (continuous line) and numerical derived stress-strain (see red circles and green square points) indicates that the developed numerical model mimics similar rock mechanical behaviors for the perforated sample.

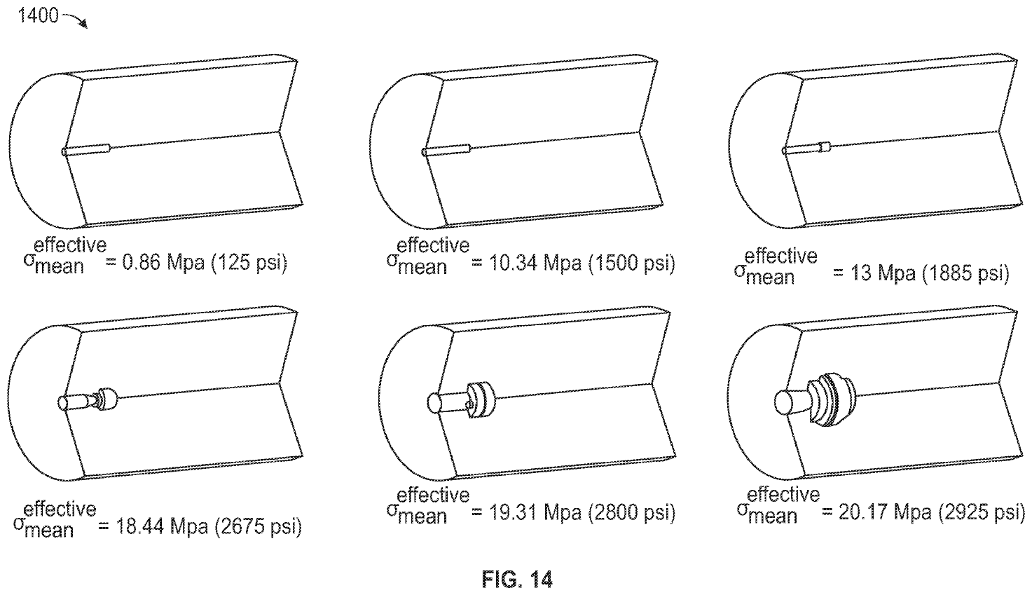

FIG. 14 shows a series of example plots 1400 as to various trial results. The series of plots 1400 include plots for different stress values ranging from 0.86 MPa to 20.17 MPa. Specifically, the series of plots 1400 show progressive perforation (grey) failure and cavity stabilization using numerical modelling techniques for Sample 1 at different mean effective stresses.

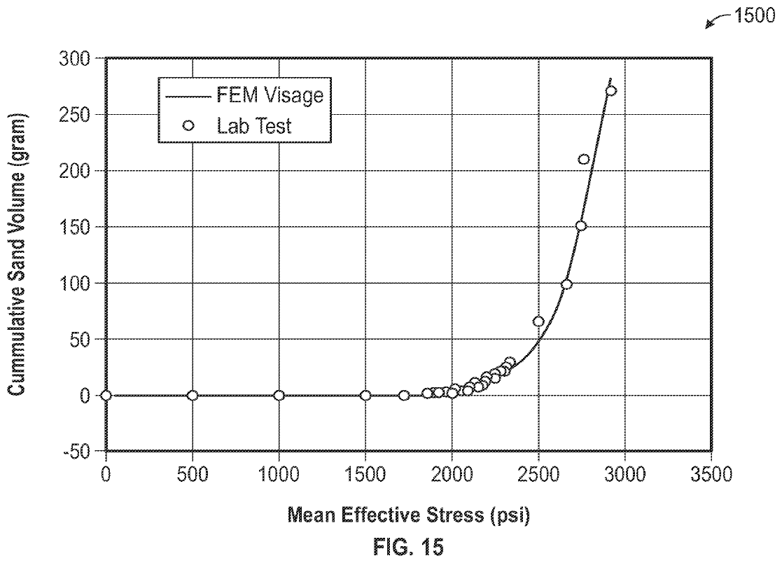

FIG. 15 shows an example plot 1500 of simulated cumulative sand/solid grains removed from perforation cells using an example numerical technique and actual sand/solid production on a core sample in the lab versus mean effective stress (psi). As shown, the results of the numerical technique (e.g., FEM engine of the VISAGE framework as implemented in the method 1000 of FIG. 10) provide close agreement with the laboratory results (red circles) over a range of mean effective stress from 0 to 3000 psi (e.g., approximately 20 MPa). The plot 1500 demonstrates the predictive power of the deployed technique. The model was able to predict the sand/solid mass at various loading steps. Based on this laboratory test validation, the adopted sand/solid production technique and failure criterion can be used, for example, to quantify the failure zone and sand/solid production volume and rate in the hydrocarbon producing wells.

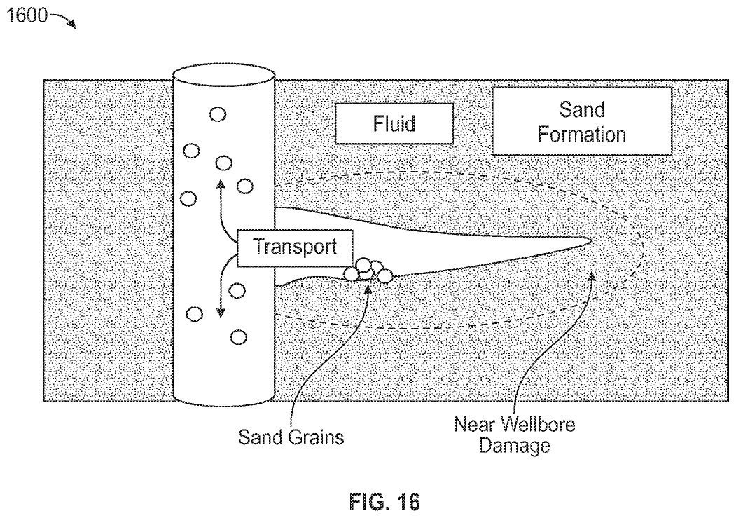

FIG. 16 shows an example of a diagram of failure at a perforation/borehole with sand/solid production and cavity expansion. Such phenomena can be modeled using geomechanics where one or more features of the method 1100 may be implemented for sand/solid volume estimation, for example, at a wellbore condition.

Sand/solid production can occur in a hydrocarbon well when formation sand/solid is produced together with hydrocarbon (e.g., at a surface station, a seabed station, a downhole pump, etc.). In many instances, such a scenario is undesirable for operators as it can increase risk of equipment failure and increase completion costs. As a reservoir matures (e.g., becomes depleted), higher severity and risk of sand/solid production from reservoir rock may be expected. Hence, a deeper understanding of reservoir rock geomechanical response to pressure changes and its impact to sand/solid production can benefit operators for field development planning (e.g., completion design, production rates and well intervention).

In various instances, sand/solid production occurrence can be divided into two stages. During a first stage, reservoir formation rock fails as may be caused by stresses due to differential pressure between reservoir and bottom hole flowing pressure. Physical phenomena of a second stage can be driven by the producing fluid velocity where energy carries sand/solid to a station (e.g., surface station, etc.). In the event that the velocity or the energy is(are) insufficient, sand/solid may travel under the influence of gravity and, for example, settle at a bottom of a hole and/or at a lateral portion of a hole (e.g., as in a deviated and/or horizontal well).

Few options exist in the industry today to minimize sanding or completely avoid sanding. Without knowing the severity of sand/solid production risk including sand/solid propensity, selecting the best and optimum completion for a well can be a complicated decision or process. Both over-engineering and under-estimating the risk can overall cause higher costs whether at the beginning stage or unwanted costs for well intervention. Therefore, a proper design based on a geomechanical model is highly recommended. We discussed in detail below the steps required to construct a geomechanical model for modeling sand/solid production propensity.

As an example, a method can include building a mechanical earth model (MEM), constructing a numerical grid (e.g., or mesh) for a wellbore and a perforation, and performing a numerical simulation utilizing one or more simulators for progressive cavity failure and stabilization. Such a method can further include estimation of sand/solid volumes with respect to time for one or more periods, for example, which may pertain to production for planned drawdown, etc.

As to building a MEM, consider building a geomechanics model MEM that may be focused on one or more reservoir sections and that is fit for analyzing sand/solid failure tendency during oil/gas production. Such an approach can aim to construct a 1 D, 2D or 3D MEM to derive rock mechanical properties, pore pressure and in-situ stress state in a study well. Such a model can be validated via wellbore stability analysis, for example, by comparing predicted drilling induced wellbore failures with actual drilling observations, caliper and image log (e.g., as may be available). As to constructing a numerical grid for a wellbore and one or more perforations, consider a 3D FEM grid constructed for desired wellbore structure, which may include using structured and/or unstructured grids (meshing).

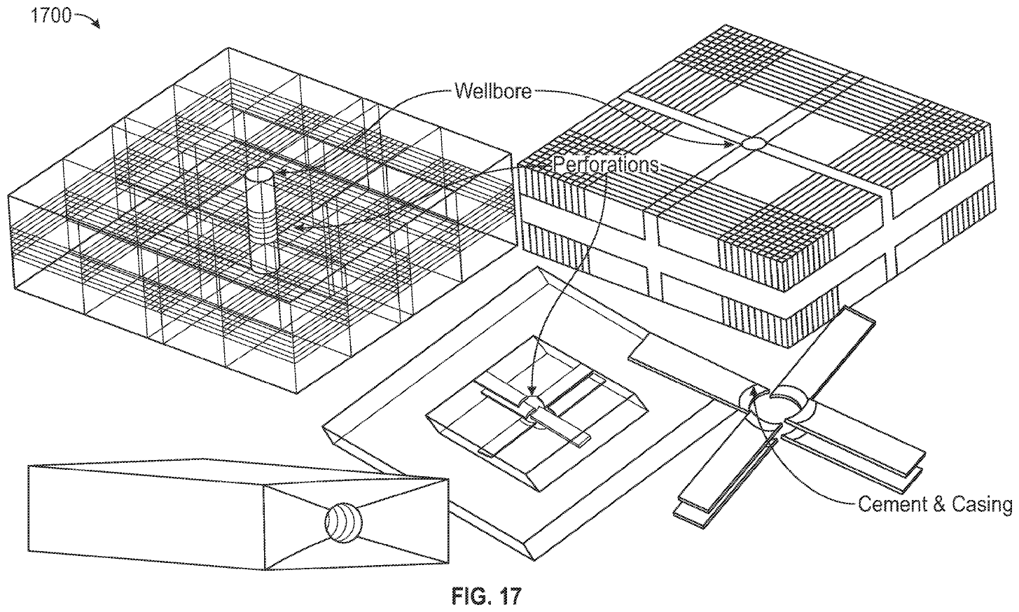

FIG. 17 shows an example of a numerical FEM model structures 1700 for a well, referred to as well 1, which represents a perforated vertical well case. As shown, the structures 1700 include a wellbore, perforations and cement and casing.

As explained, a method can include performing numerical simulation for progressive cavity failure and stabilization. Such a method may utilize one or more model structures, for example, as illustrated in FIG. 17.

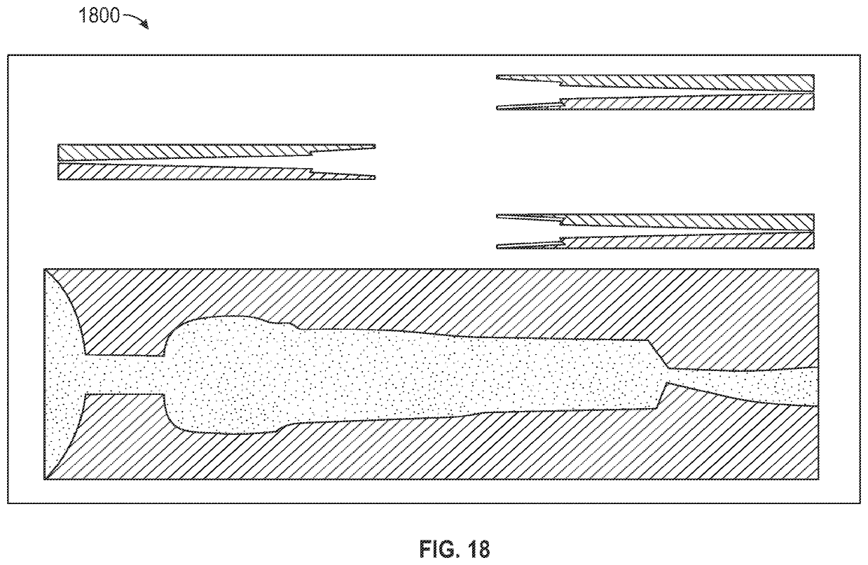

FIG. 18 shows example views 1800, cross-section and top views, of progressive cavity failure along a perforation during production that leads to sand/solid production. Specifically, FIG. 18 shows views of progressive failure of the perforation tunnels during hydrocarbon production.

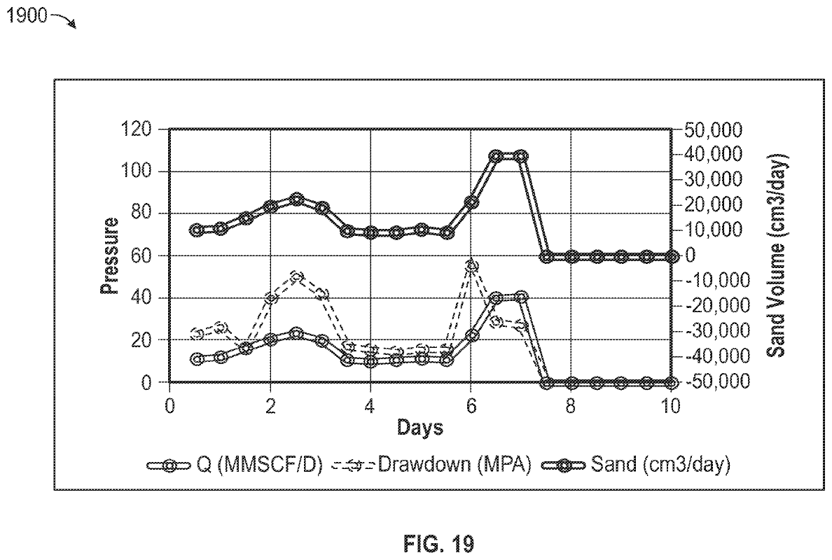

FIG. 19 shows an example plot 1900 of pressure and sand volume production with respect to time. Such data can be generated using a numerical model and simulation where various conditions are utilized for characterizing cells, which can provide for effective “removal” of cells without re-gridding/re-meshing. In the plot 1900, removed grid cells can be quantified to provide estimates of volume of produced sand/solid for given drawdown.

As an example, a method can include accounting for permeability, porosity, void fraction, etc., during a cell “removal” process. Such an approach may aim to provide for one or more mass balances. For example, consider a formation matrix type of mass balance and/or a fluid or fluids mass balance. As an example, an amount of sand/solid estimate may be based at least in part on one or more physical characteristics of material (e.g., rock, etc.). As an example, a method may be applied to one or more types of materials (e.g., sand, carbonate, etc.).

A method can include constructing a numerical model of a material matrix, where the numerical model includes cells; performing a simulation of physical phenomena with respect to time using the numerical model; during the performing, analyzing one of the cells as to physical characteristics of the material matrix; and, responsive to the analyzing and during the performing, assigning one or more properties to the cell that indicate failure of the material matrix of the cell without removing the cell from the numerical model, without re-meshing the numerical model, etc.

As an example, a black oil fluid model may be utilized as a physics-based model. Black oil can refer to a general type of crude oil that includes alkanes (e.g., of C5 to C30+). Black oil can include a wide variety of chemical species including large, heavy, nonvolatile molecules.

A black oil model can provide for fluid property correlations that cover various types of petroleum fluids, from extra heavy oil to light oil and condensate, and may also be used for simplified gas, utility fluids, and other scenarios. A black oil model may provide for a wide range of viscosity correlations with options for specified dead oil and emulsion viscosities. In various examples, a range of emulsion correlations can cover tight to light emulsion types with optional specification of emulsion tables and optional specification or calculation of the inversion point. A black oil model may provide for specification of gas contaminants, which may be used for compressibility factor adjustment and corrosion calculations. In various examples, a black oil model can provide for specification of thermal data for phases of a black oil fluid for accurate thermal modeling and methods for fluid enthalpy calculation for accurate energy-balance prediction. A black oil model can provide for comprehensive fluid mixing rules.

A black oil model can be described using so-called black oil equations, which can be a set of partial differential equations that describe fluid flow, for example, in a petroleum reservoir for purposes of black-oil reservoir fluid flow simulation. A black oil model can include water modeled explicitly together with two hydrocarbon components, one (pseudo) oil phase and one (pseudo-) gas phase. As an example, another type of model can be utilized such as a compositional model or formulation, in which each hydrocarbon component is handled separately.

Example equations of an extended black-oil model can include:

$$\frac{\partial }{\partial t} [ ϕ ( \frac{{S}_{o}}{{B}_{o}} + \frac{{R}_{V} {S}_{g}}{{B}_{g}} ) ] + ∇ \cdot ( \frac{1}{{B}_{o}} {\vec{u}}_{o} + \frac{{R}_{V}}{{B}_{g}} {\vec{u}}_{g} ) = 0$$

$$\frac{\partial }{\partial t} [ ϕ ( \frac{{S}_{w}}{{B}_{w}} ) ] + ∇ \cdot ( \frac{1}{{B}_{w}} {\vec{u}}_{w} ) = 0$$

$$\frac{\partial }{\partial t} [ ϕ ( \frac{{S}_{g}}{{B}_{g}} + \frac{{R}_{S} {S}_{o}}{{B}_{o}} ) ] + ∇ \cdot ( \frac{{R}_{S}}{{B}_{o}} {\vec{u}}_{o} + \frac{1}{{B}_{g}} {\vec{u}}_{g} ) = 0$$

The foregoing equations include porosity of the porous medium, SW as water saturation, Sₒ and S_{g} as saturations of liquid (oil) and vapor (gas) phases, and Darcy velocities of the liquid phase, water phase and vapor phase. Oil and gas at the surface (standard conditions) that could be produced from both liquid and vapor phases existing at high pressure and temperature of reservoir conditions can be characterized by Bₒ as an oil formation volume factor (ratio of some volume of reservoir liquid to the volume of oil at standard conditions obtained from the same volume of reservoir liquid), B_{w} as a water formation volume factor (ratio of volume of water at reservoir conditions to volume of water at standard conditions), B_{g} as a gas formation volume factor (ratio of some volume of reservoir vapor to the volume of gas at standard conditions obtained from the same volume of reservoir vapor), R_{S} as a solution of gas in oil phase (ratio of volume of gas to the volume of oil at standard conditions obtained from some amount of liquid phase at reservoir conditions), R_{V} as a vaporized oil in gas phase (ratio of volume of oil to the volume of gas at standard conditions obtained from some amount of vapor phase at reservoir conditions).

A dynamic multiphase flow simulator may model time-dependent behaviors, or transient flow, which can facilitate maximization of production. A simulator may be utilized in offshore and/or onshore developments as to transient behavior in pipelines, wellbores, etc. Transient simulation with a simulator can provide an added dimension to steady-state analyses by predicting system dynamics such as time-varying changes in flow rates, fluid compositions, temperature, solids deposition and operational changes.

As an example, one or more types of equipment may be selected, controlled, etc., utilizing simulation results as to failure of one or more cells of a model, which, as mentioned, may indicate fluid producible material of a material matrix.

As an example, a choke can be a device incorporating an orifice that is used to control fluid flow rate or downstream system pressure. Chokes may be available in various configurations, for example, for one or more of fixed and adjustable modes of operation. As an example, an adjustable choke may enable fluid flow and pressure parameters to be changed to suit process or production requirements, optionally via a controller that is operatively coupled to an actuator that can adjust one or more pieces of the choke. As to a fixed choke, it may be more resistant to erosion under prolonged operation or production of abrasive fluids than various adjustable chokes. As an example, a well may be fitted with a choke that can be selected and/or controlled to suit desired operational parameters (e.g., flow rate, production, etc.).

As an example, one or more artificial lift processes may be utilized in one or more field operations. Artificial lift can include, for example, a surface pump (e.g., a sucker rod pump), a downhole pump (e.g., an electric submersible pump), gas lift, etc.

As to gas lift, it is a process where, for example, gas may be injected from an annulus into tubing. An annulus, as applied to an oil well or other well for recovering a subsurface resource may refer to a space, lumen, or void between piping, tubing or casing and the piping, tubing, or casing immediately surrounding it, for example, at a greater radius.

As an example, injected gas may aerate well fluid in production tubing in a manner that “lightens” the well fluid such that the fluid can flow more readily to a surface location. As an example, one or more gas lift valves may be configured to control flow of gas during an intermittent flow or a continuous flow gas lift operation. As an example, a gas lift valve may operate based at least in part on a differential pressure control that can actuate a valve mechanism of the gas lift valve.

As an example, a system may operate to model and simulate reserves of oil and/or one or more other fluids (e.g., water, gas, etc.). For example, consider utilization of computational reservoir characterization tools that provide for stratigraphic and structural reservoir understanding, which can involve conversion of 2D maps to 3D models. Such tools may provide for reservoir characterizations during one or more phases of an exploration, development, and production lifecycle.

As explained, by simulation of a various aspects of a material matrix, where such a material matrix collapses, loses strength, loses binding of particles, etc., material may be liberated that can be amenable to flow by a flow field (e.g., pressure driven, etc.) and/or by gravity. As explained, liberated material can provide information as to field operations, which may relate to production, effectiveness of a stimulation (e.g., a treatment, etc.), equipment wear, equipment operation, flooding or other injecting, etc.

As an example, an electric submersible pump (ESP) may be an example of equipment that may be placed in a geologic environment. As an example, an ESP may be expected to function in an environment over an extended period of time (e.g., optionally of the order of years). An ESP may be subjected to greater wear upon production of solids and/or one or more performance issues. For example, consider wear due to sand of one or more impellers, diffusers and/or other structures. During operation of an ESP, a condition known as sanding may occur.

Wear processes inside an ESP can be classified by different modes of mechanisms. Erosive wear can be observed in the primary flow channel of the impeller (rotor) and diffuser (stator). Particles strike shroud surfaces and the scratched material can be flushed away by fluid. In a secondary flow region, balance chamber and sealing rings, particles may be present between the stator and the rotating rotor such that abrasive wear may dominate a wearing process. Abrasion tends to be more complicated that erosion as abrasion equations can depend on geometries, physical mechanism and load between particle and target surface.

As an example, liberated material may flow along one or more cables, tubings, etc., in a borehole where such material may give rise to one or more wear issues. For example, an ESP may be deployed using a cable where the cable can include an outer protective layer. Increased liberation of material may impact the outer protective layer and affect its properties (e.g., insulating, bending, etc.).

As explained, sand and/or other solids liberation may present issues where a bore is deviated, which may be horizontal. Various types of equipment may find use in a deviated borehole. For example, consider utilizing an ESP in a horizontal well to increase production where liberated material may settle along the wellbore and/or in one or more portions of the ESP rather than settling downhole as may be expected in a vertical well. In various scenarios, liberated material from a material matrix (e.g., rock formation, etc.) can present different types of impacts, issues, etc., which may differ as to type, extent, etc., in a manner that depends on gravity.

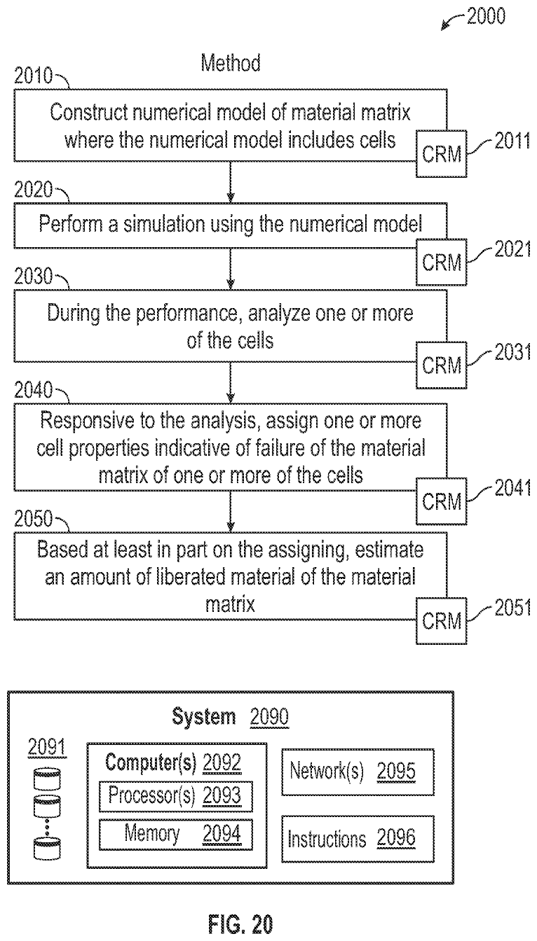

FIG. 20 shows an example of a method 2000 that includes a construction block 2010 for constructing a numerical model of a material matrix, where the numerical model includes cells; a performance block 2020 for performing a simulation of physical phenomena with respect to time using the numerical model; an analysis block 2030 for, during the performing, analyzing one of the cells as to physical characteristics of the material matrix; and an assignment block 2040 for, responsive to the analyzing and during the performing, assigning one or more properties to the cell that indicate failure of the material matrix of the cell, for example, without removing the cell from the numerical model and/or without re-gridding the numerical model. As shown, the method 2000 may include an estimation block 2050 for estimating an amount of liberated material of the material matrix based at least in part on the assigning. For example, where a material matrix of a cell fails due to one or more physical, chemical, etc., reasons, material of the material matrix may be liberated and amenable to flow in a flow field and/or settling under the influence of gravity.

The method 2000 is shown in FIG. 20 in association with various computer-readable media (CRM) blocks 2011, 2021, 2031, 2041 and 2051. Such blocks generally include instructions suitable for execution by one or more processors (or processor cores) to instruct a computing device or system to perform one or more actions. While various blocks are shown, a single medium may be configured with instructions to allow for, at least in part, performance of various actions of the method 2000. As an example, a computer-readable medium (CRM) may be a computer-readable storage medium that is non-transitory and that is not a carrier wave. As an example, one or more of the blocks 2011, 2021, 2031, 2041 and 2051 may be in the form of processor-executable instructions, for example, consider the one or more sets of instructions 270 of the system 250 of FIG. 2, etc.

In the example of FIG. 20, the system 2090 includes one or more information storage devices 2091, one or more computers 2092, one or more networks 2095 and instructions 2096. As to the one or more computers 2092, each computer may include one or more processors (e.g., or processing cores) 2093 and memory 2094 for storing the instructions 2096, for example, executable by at least one of the one or more processors 2093 (see, e.g., the blocks 2011, 2021, 2031, 2041 and 2051). As an example, a computer may include one or more network interfaces (e.g., wired or wireless), one or more graphics cards, a display interface (e.g., wired or wireless), etc.

As an example, a method can include constructing a numerical model of a material matrix, where the numerical model includes cells; performing a simulation of physical phenomena with respect to time using the numerical model; during the performing, analyzing one of the cells as to physical characteristics of the material matrix; and, responsive to the analyzing and during the performing, assigning one or more properties to the cell that indicate failure of the material matrix of the cell without removing the cell from the numerical model and/or without re-gridding (e.g., re-meshing) the numerical model. As an example, such a model can include estimating an amount of fluid flow producible material of the material matrix based at least in part on the indicated failure of the material matrix of the cell. In such an example, the fluid flow producible material may be or include sand.

As an example, a method can include assigning one or more properties to a cell that includes assigning the Young's modulus of the cell a reduced Young's modulus value. In such an example, the reduced Young's modulus value of the cell may be assigned a value of approximately zero (or exactly zero).

As an example, a method can include assigning one or more properties to a cell where such a method includes assigning the cell one or more fluid properties. For example, consider an approach where properties are assigned such that the cell no longer includes material of the material matrix, which may be liberated and consider available for flow, settling, etc.

As an example, a method can include assigning one or more properties to a cell that effectively inactivates the cell. For example, in such a method assigning one or more properties to the cell can provide for transferring pressure on the cell to at least one neighboring cell (e.g., one or more adjacent cells, etc.).

As an example, a numerical model may be a three-dimensional numerical model. Such a model may represent a subsurface region or another region. For example, consider a model of a core or other type of sample, a manufactured component, etc.

As an example, simulation of physical phenomena can include simulating a stimulation process. For example, consider one or more of a mechanical stimulation process, a chemical stimulation process or another type of stimulation process.

As an example, a stimulation may be a treatment performed to restore or enhance the productivity of a well. Stimulation treatments may fall into two main groups, hydraulic fracturing treatments and matrix treatments. Fracturing treatments may be performed above the fracture pressure of a reservoir formation and create a highly conductive flow path between the reservoir and a wellbore. As an example, a matrix treatment may be performed below a reservoir fracture pressure and be designed to restore permeability of the reservoir following damage to the near-wellbore area. Stimulation in shale gas reservoirs can include one or more types of hydraulic fracturing treatments.

As an example, a method can include simulation of physical phenomena that includes producing fluid from a reservoir. In such an example, simulation of physical phenomena can include accounting for gravity. For example, consider modeling settling of a material matrix for a cell.

As an example, a method can include performing a simulation that includes geomechanical simulation. For example, consider equations for cells that can utilize one or more physical properties of a cell such as, for example, a Young's modulus. The Young's modulus is an elastic parameter named after British physicist Thomas Young that characterizes the ratio of longitudinal stress to longitudinal strain. As an example, one or more elastic parameters may be utilized. Elastic parameters may include elastic moduli that define properties of material that can undergo stress, deformation, and then recover and return to an original shape after the stress ceases. Elastic constants may include the bulk modulus, Lame constant, Poisson's ratio, shear modulus, and Young's modulus. Elastic constants may be utilized in seismology as velocity of waves can depend on the elastic constants and density of the rock. As an example, a parameter may be a yield stress. A yield stress can be an amount of stress applied to a material to make it begin to flow or to yield. As an example, a parameter can be a yield point. A yield point can be an elastic limit or the point at which a material can no longer deform elastically. For example, when the elastic limit is exceeded by an applied stress, permanent deformation occurs. As an example, depending on properties of a material matrix, application of stress at or beyond a yield point can cause the material matrix to yield and, for example, break into smaller pieces, which may liberate at least a portion of the material. Depending on the nature of a material matrix, its properties may depend on temperature, salinity, pH, pressure, etc. As mentioned, a stimulation may include chemical treatment such as acid treatment. As explained, one or more phenomena may cause a material matrix to collapse and liberate material.

As an example, a material matrix can be a cylindrical material matrix. For example, consider a cylindrical material matrix that represents a core sample and/or an annular region about a borehole. As an example, a material matrix can be a reservoir. For example, consider sandstone material, carbonate material, etc.

As an example, a system can include a processor; memory accessible to the processor; and processor-executable instructions stored in the memory to instruct the system to: construct a numerical model of a material matrix, where the numerical model includes cells; perform a simulation of physical phenomena with respect to time using the numerical model; during the performance, analyze one of the cells as to physical characteristics of the material matrix; and responsive to the analysis and during the performance, assign one or more properties to the cell that indicate failure of the material matrix of the cell without removing the cell from the numerical model and/or without re-gridding the numerical model.

As an example, one or more computer-readable storage media can include processor-executable instructions to instruct a computing system to: construct a numerical model of a material matrix, where the numerical model includes cells; perform a simulation of physical phenomena with respect to time using the numerical model; during the performance, analyze one of the cells as to physical characteristics of the material matrix; and responsive to the analysis and during the performance, assign one or more properties to the cell that indicate failure of the material matrix of the cell without removing the cell from the numerical model and/or without re-gridding the numerical model.

As an example, a computer program product can include computer-executable instructions to instruct a computing system to perform one or more methods such as, for example, the method 2000 of FIG. 20, etc.

As an example, a computer program product can include one or more computer-readable storage media that can include processor-executable instructions to instruct a computing system to perform one or more methods and/or one or more portions of a method.

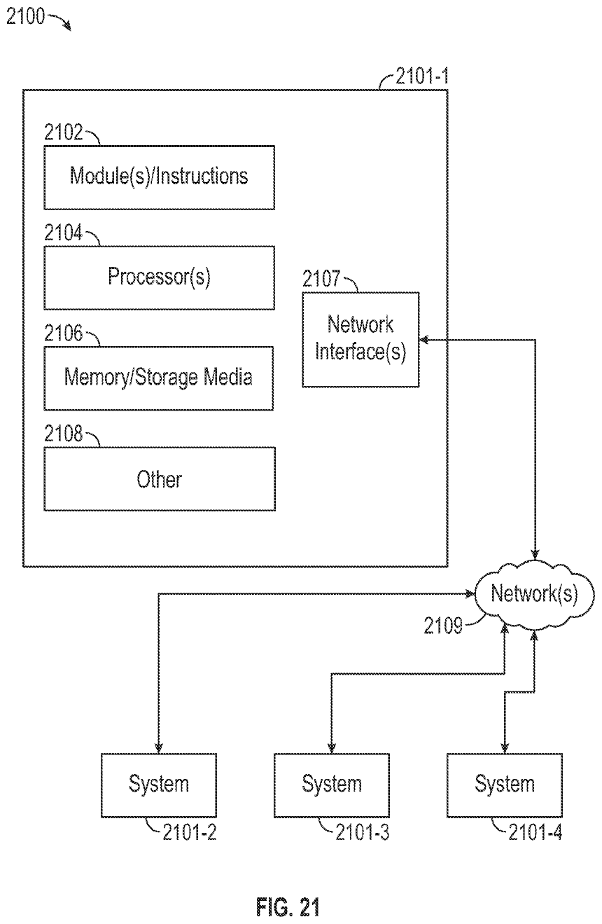

In some embodiments, a method or methods may be executed by a computing system. FIG. 21 shows an example of a system 2100 that can include one or more computing systems 2101-1, 2101-2, 2101-3 and 2101-4, which may be operatively coupled via one or more networks 2109, which may include wired and/or wireless networks.

As an example, a system can include an individual computer system or an arrangement of distributed computer systems. In the example of FIG. 21, the computer system 2101-1 can include one or more modules 2102, which may be or include processor-executable instructions, for example, executable to perform various tasks (e.g., receiving information, requesting information, processing information, simulation, outputting information, etc.).

As an example, a module may be executed independently, or in coordination with, one or more processors 2104, which is (or are) operatively coupled to one or more storage media 2106 (e.g., via wire, wirelessly, etc.). As an example, one or more of the one or more processors 2104 can be operatively coupled to at least one of one or more network interface 2107. In such an example, the computer system 2101-1 can transmit and/or receive information, for example, via the one or more networks 2109 (e.g., consider one or more of the Internet, a private network, a cellular network, a satellite network, etc.).

As an example, the computer system 2101-1 may receive from and/or transmit information to one or more other devices, which may be or include, for example, one or more of the computer systems 2101-2, etc. A device may be located in a physical location that differs from that of the computer system 2101-1. As an example, a location may be, for example, a processing facility location, a data center location (e.g., server farm, etc.), a rig location, a wellsite location, a downhole location, etc.

As an example, a processor may be or include a microprocessor, microcontroller, processor module or subsystem, programmable integrated circuit, programmable gate array, or another control or computing device.

As an example, the storage media 2106 may be implemented as one or more computer-readable or machine-readable storage media. As an example, storage may be distributed within and/or across multiple internal and/or external enclosures of a computing system and/or additional computing systems.

As an example, a storage medium or storage media may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLUERAY disks, or other types of optical storage, or other types of storage devices.

As an example, a storage medium or media may be located in a machine running machine-readable instructions or located at a remote site from which machine-readable instructions may be downloaded over a network for execution.

As an example, various components of a system such as, for example, a computer system, may be implemented in hardware, software, or a combination of both hardware and software (e.g., including firmware), including one or more signal processing and/or application specific integrated circuits.

As an example, a system may include a processing apparatus that may be or include a general-purpose processors or application specific chips (e.g., or chipsets), such as ASICs, FPGAs, PLDs, or other appropriate devices.

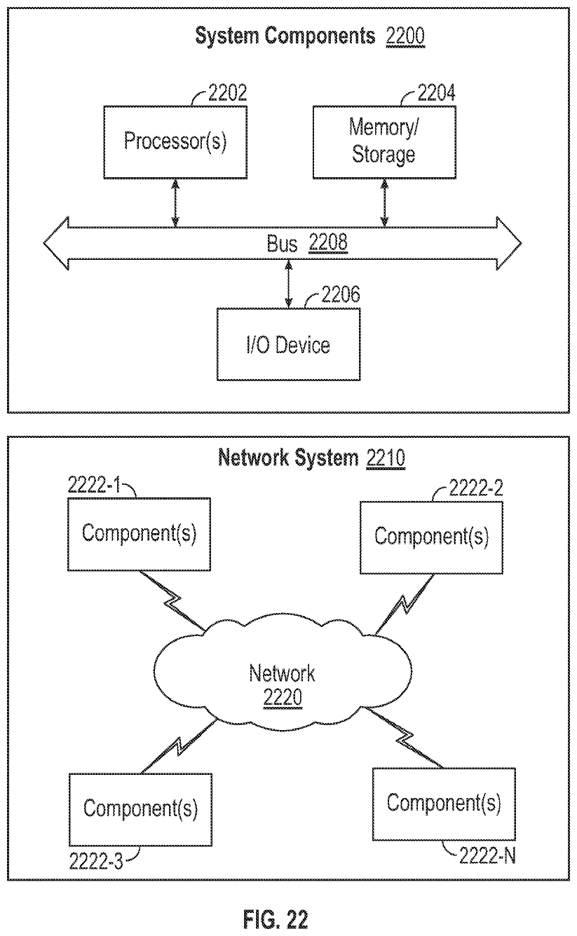

FIG. 22 shows components of an example of a computing system 2200 and an example of a networked system 2210 with a network 2220. The system 2200 includes one or more processors 2202, memory and/or storage components 2204, one or more input and/or output devices 2206 and a bus 2208. In an example embodiment, instructions may be stored in one or more computer-readable media (e.g., memory/storage components 2204). Such instructions may be read by one or more processors (e.g., the processor(s) 2202) via a communication bus (e.g., the bus 2208), which may be wired or wireless. The one or more processors may execute such instructions to implement (wholly or in part) one or more attributes (e.g., as part of a method). A user may view output from and interact with a process via an I/O device (e.g., the device 2206). In an example embodiment, a computer-readable medium may be a storage component such as a physical memory storage device, for example, a chip, a chip on a package, a memory card, etc. (e.g., a computer-readable storage medium).

In an example embodiment, components may be distributed, such as in the network system 2210. The network system 2210 includes components 2222-1, 2222-2, 2222-3, . . . 2222-N. For example, the components 2222-1 may include the processor(s) 2202 while the component(s) 2222-3 may include memory accessible by the processor(s) 2202. Further, the component(s) 2222-2 may include an I/O device for display and optionally interaction with a method. The network 2220 may be or include the Internet, an intranet, a cellular network, a satellite network, etc.

As an example, a device may be a mobile device that includes one or more network interfaces for communication of information. For example, a mobile device may include a wireless network interface (e.g., operable via IEEE 802.11, ETSI GSM, BLUETOOTH, satellite, etc.). As an example, a mobile device may include components such as a main processor, memory, a display, display graphics circuitry (e.g., optionally including touch and gesture circuitry), a SIM slot, audio/video circuitry, motion processing circuitry (e.g., accelerometer, gyroscope), wireless LAN circuitry, smart card circuitry, transmitter circuitry, GPS circuitry, and a battery. As an example, a mobile device may be configured as a cell phone, a tablet, etc. As an example, a method may be implemented (e.g., wholly or in part) using a mobile device. As an example, a system may include one or more mobile devices.

As an example, a system may be a distributed environment, for example, a so-called “cloud” environment where various devices, components, etc. interact for purposes of data storage, communications, computing, etc. As an example, a device or a system may include one or more components for communication of information via one or more of the Internet (e.g., where communication occurs via one or more Internet protocols), a cellular network, a satellite network, etc. As an example, a method may be implemented in a distributed environment (e.g., wholly or in part as a cloud-based service).

As an example, information may be input from a display (e.g., consider a touchscreen), output to a display or both. As an example, information may be output to a projector, a laser device, a printer, etc. such that the information may be viewed. As an example, information may be output stereographically or holographically. As to a printer, consider a 2D or a 3D printer. As an example, a 3D printer may include one or more substances that can be output to construct a 3D object. For example, data may be provided to a 3D printer to construct a 3D representation of a subterranean formation. As an example, layers may be constructed in 3D (e.g., horizons, etc.), geobodies constructed in 3D, etc. As an example, holes, fractures, etc., may be constructed in 3D (e.g., as positive structures, as negative structures, etc.).

Although only a few example embodiments have been described in detail above, those skilled in the art will readily appreciate that many modifications are possible in the example embodiments. Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures.

What is claimed is:

1. A method comprising:
constructing a numerical model of a material matrix, wherein the numerical model comprises cells;
performing a simulation of physical phenomena with respect to time using the numerical model;
during the performing, analyzing one of the cells as to physical characteristics of the material matrix; and
responsive to the analyzing and during the performing, assigning one or more properties to the cell that indicate failure of the material matrix of the cell without removing the cell from the numerical model.

2. The method of claim 1, comprising estimating an amount of fluid flow producible material of the material matrix based at least in part on the indicated failure of the material matrix of the cell.

3. The method of claim 2, wherein the fluid flow producible material comprises sand.

4. The method of claim 1, wherein the assigning one or more properties to the cell comprises assigning the Young's modulus of the cell a reduced Young's modulus value.

5. The method of claim 4, wherein the reduced Young's modulus value of the cell is assigned a value of approximately zero.

6. The method of claim 1, wherein the assigning one or more properties to the cell comprises assigning the cell one or more fluid properties.

7. The method of claim 1, wherein the assigning one or more properties to the cell effectively inactivates the cell.

8. The method of claim 1, wherein the assigning one or more properties to the cell comprises transferring pressure on the cell to at least one neighboring cell.

9. The method of claim 1, wherein the numerical model comprises a three-dimensional numerical model.

10. The method of claim 1, wherein the simulation of physical phenomena comprises simulating a stimulation process.

11. The method of claim 10, wherein the stimulation process comprises a mechanical stimulation process.

12. The method of claim 10, wherein the stimulation process comprises a chemical stimulation process.

13. The method of claim 1, wherein the simulation of physical phenomena comprises producing fluid from a reservoir.

14. The method of claim 13, wherein the simulation of physical phenomena comprises accounting for gravity.

15. The method of claim 14, wherein the accounting for gravity comprises modeling settling of material of the material matrix for the cell.

16. The method of claim 1, wherein the material matrix comprises a cylindrical material matrix.

17. The method of claim 16, wherein the cylindrical material matrix represents a core sample.

18. The method of claim 1, wherein the material matrix comprises a reservoir.

19. A system comprising:
a processor;
memory accessible to the processor; and
processor-executable instructions stored in the memory to instruct the system to:
construct a numerical model of a material matrix, wherein the numerical model comprises cells;
perform a simulation of physical phenomena with respect to time using the numerical model;
during the performance, analyze one of the cells as to physical characteristics of the material matrix; and
responsive to the analysis and during the performance, assign one or more properties to the cell that indicate failure of the material matrix of the cell without removing the cell from the numerical model.

20. One or more computer-readable storage media comprising processor-executable instructions to instruct a computing system to:
construct a numerical model of a material matrix, wherein the numerical model comprises cells;
perform a simulation of physical phenomena with respect to time using the numerical model;
during the performance, analyze one of the cells as to physical characteristics of the material matrix; and
responsive to the analysis and during the performance, assign one or more properties to the cell that indicate failure of the material matrix of the cell without removing the cell from the numerical model.
